(19) United States
(12) Patent Application Publication
(10) Pub. No.: US 2026/0120773 A1
(43) Pub. Date: Apr. 30, 2026

(54) MEMORY SYSTEM

(71) Applicant: Kioxia Corporation, Tokyo (JP)

(72) Inventors: Yousuke HARADA, Yokohama Kanagawa (JP); Hajime YAMAZAKI, Kawasaki Kanagawa (JP)

(21) Appl. No.: 19/070,388

(22) Filed: Mar. 4, 2025

(30) Foreign Application Priority Data
Oct. 30, 2024 (JP) 2024-190589

(51) Int. Cl. G11C 16/26; G11C 16/08; G11C 16/16

(52) U.S. Cl. CPC G11C 16/26; G11C 16/08; G11C 16/16

(57) ABSTRACT

A memory system includes a memory cell array, a peripheral circuit that controls the memory cell array, a controller, and a main memory. The main memory includes a first memory area which is a unit of access by the controller. The controller classifies a plurality of word lines of the memory cell array into word line groups, and stores in the first memory area, first information including a program status of a nonvolatile memory cell group connected to a first word line group including a first word line, and a first candidate value. The controller determines, according to the first information, whether to execute a first read operation, and if so, transmits a first read command to the peripheral circuit. The peripheral circuit, in response thereto, performs a sense operation on a first nonvolatile memory cell connected to the first word line using the first candidate value.

### CROSS-REFERENCE TO RELATED APPLICATION(S)

This application is based upon and claims the benefit of priority from Japanese Patent Application No. 2024-190589, filed Oct. 30, 2024, the entire contents of which are incorporated herein by reference.

### FIELD

Embodiments described herein relate generally to a memory system.

### BACKGROUND

A memory system including a nonvolatile memory such as a NAND flash memory and a memory controller that controls the nonvolatile memory is known.

### BRIEF DESCRIPTION OF THE DRAWINGS

FIG. 1 shows a configuration of a memory system according to a first embodiment.

FIG. 2 shows a circuit configuration of a block according to the first embodiment.

FIGS. 3A to 3C show a threshold voltage distribution of a memory cell transistor according to the first embodiment.

FIG. 4 shows an example of grouping of word line groups according to the first embodiment.

FIG. 5 shows a word line group allocation table according to the first embodiment.

FIG. 6 shows a shift table according to the first embodiment.

FIG. 7 shows a history value table according to the first embodiment.

FIG. 8 is a flowchart showing an example of a read sequence according to the first embodiment.

FIG. 9 is a flowchart showing an example of an edge word line determination operation according to the first embodiment.

FIG. 10 is a flowchart showing an example of a history value read operation according to the first embodiment.

FIG. 11 is a flowchart showing an example of a learning read operation according to the first embodiment.

FIG. 12 is a flowchart showing an example of a write process according to the first embodiment.

FIG. 13 shows a history value table according to a second embodiment.

FIGS. 14A to 14D show an example of a transition of the number of unprogrammed word lines according to the second embodiment.

FIG. 15 is a flowchart showing an example of an edge word line determination operation according to the second embodiment.

FIG. 16 is a flowchart showing an example of a write process according to the second embodiment.

FIG. 17 shows a history value table according to a third embodiment.

FIGS. 18A to 18F show an example of a transition of the number of unprogrammed cell units according to the third embodiment.

FIG. 19 is a flowchart showing an example of a read sequence according to the third embodiment.

FIG. 20 is a flowchart showing an example of an edge word line determination operation according to the third embodiment.

FIG. 21 is a flowchart showing an example of a write process according to the third embodiment.

### DETAILED DESCRIPTION

Embodiments provide a memory system capable of curbing an increase in latency.

In general, according to one embodiment, a memory system includes a memory cell array, a peripheral circuit, a main memory, and a memory controller. The peripheral circuit controls the memory cell array. The memory controller is electrically connected to the peripheral circuit. The main memory is included in or electrically connected to the memory controller. The memory cell array includes a plurality of word lines and a plurality of nonvolatile memory cells connected to the plurality of word lines. The main memory includes a first memory area that is a unit of access by the memory controller. The memory controller classifies the plurality of word lines into at least one word line group. A first word line group among the at least one word line group includes a first word line among the plurality of word lines. The plurality of nonvolatile memory cells include a first nonvolatile memory cell group connected to the first word line group. The first word line is connected to the first nonvolatile memory cell in the first nonvolatile memory cell group. The memory controller stores in the first memory area, first information indicating a program status of the first nonvolatile memory cell group and a first candidate value. The memory controller determines according to the first information whether to execute a first read operation. The memory controller, in response to determining to execute the first read operation, transmits a first read command to execute a sense operation using the first candidate value to the peripheral circuit. The peripheral circuit, in response to receiving the first read command from the memory controller, performs a sense operation on the first nonvolatile memory cell using the first candidate value.

Embodiments will be described below with reference to the accompanying drawings. In the following description, components having substantially the same functions and configurations are denoted by the same reference numerals, and repeated descriptions may be omitted. All descriptions of one embodiment also apply to other embodiments, unless expressly or obviously excluded.

The sizes of figures in the drawings, or a size relationship of figures does not indicate the actual size or size relationship of the configurations and data represented by those figures.

Each functional block can be implemented as either hardware or computer software, or as a combination thereof. For this reason, each functional block is generally described in terms of its function so that it is clear that each functional block can be either of these. In addition, it is not essential that each functional block be distinguished as in the following example. For example, some functions may be executed by a functional block other than the illustrated functional block. Furthermore, the illustrated functional block may be further divided into smaller functional subblocks.

In addition, any steps in a flow of a method according to an embodiment are not limited to the illustrated order, and unless otherwise indicated, they can be executed in an order different from the illustrated order and (or) in parallel with other steps.

### 1. First Embodiment

A memory system according to a first embodiment will be described below. Hereinafter, a NAND flash memory as a nonvolatile memory and a memory system equipped with the NAND flash memory will be described as an example, but the embodiment is not limited thereto. That is, memories other than the NAND flash memory, such as a resistance random access memory (ReRAM) and a ferroelectric random access memory (FeRAM), can also be used as the nonvolatile memory. In addition, it is not essential that the nonvolatile memory be a semiconductor memory, and this embodiment can also be applied to various storage media other than the semiconductor memory.

### 1.1 Configuration of Memory System

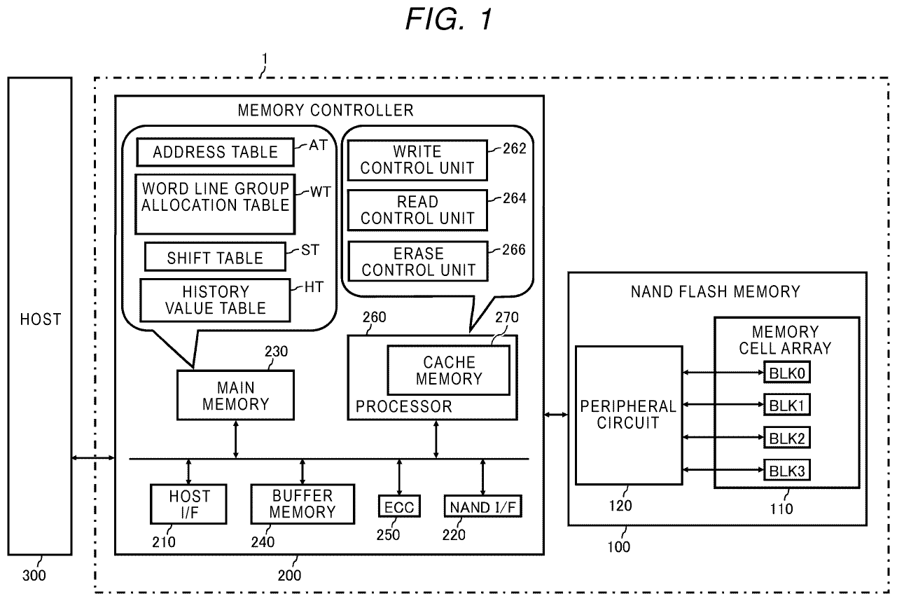

First, an outline of a configuration of the memory system according to this embodiment will be described with reference to FIG. 1.

As shown in FIG. 1, a memory system 1 includes a nonvolatile memory (NAND flash memory) 100 and a memory controller 200. The memory system 1 may be configured with a plurality of semiconductor chips. The NAND flash memory 100 and the memory controller 200 may be combined to form a single memory system 1. Examples of such a device include a universal flash storage (UFS) device, a memory card such as an SD™ card, a solid state drive (SSD), and an embedded multimedia card (eMMC).

The NAND flash memory 100 includes a plurality of memory cells (hereinafter also referred to as memory cell transistors MT) and stores data in a nonvolatile manner. The NAND flash memory 100 may have a structure in which, for example, a memory chip MC and a CMOS chip CC are bonded together.

The memory controller 200 is connected to the NAND flash memory 100 via a NAND bus and connected to a host 300 via a host bus. The memory controller 200 controls the NAND flash memory 100. The memory controller 200 also accesses the NAND flash memory 100 in response to a request received from the host 300.

The host 300 may be, for example, a mobile phone, a tablet, a personal computer, a server, or an automobile. The host 300 may conform to various standard interfaces, for example, an SD™ interface, a serial attached small computer system interface (SCSI) (SAS), serial advanced technology attachment (ATA) (SATA), peripheral component interconnect express (PCI Express™) (PCIe™), or nonvolatile memory express (NVM Express™) (NVMe™).

The NAND bus transmits and receives signals according to a NAND interface. Signals transmitted and received by the NAND bus include a command CMD, an address ADD, and data DAT such as write data and read data.

### 1.2 Configuration of Memory Controller

Next, a configuration of the memory controller 200 will be described. Each function of the memory controller 200 may be implemented by a dedicated circuit, or may be implemented by a processor 260 executing firmware. A portion of the configuration of the memory controller 200 may be provided outside the memory controller 200, as long as the portion is electrically connected to at least one of the other components of the memory controller 200.

The memory controller 200 is, for example, a system-on-a-chip (SoC). The memory controller 200 may be configured with a plurality of semiconductor chips. The memory controller 200 includes a host interface circuit (host I/F) 210, a NAND interface circuit (NAND I/F) 220, a main memory 230, a buffer memory 240, an error checking and correction (ECC) circuit 250, and a processor 260.

The host interface circuit 210 is connected to the host 300 via the host bus. The host interface circuit 210 transfers requests and data received from the host 300 to the processor 260 and the buffer memory 240, respectively. The host interface circuit 210 also transfers the data in the buffer memory 240 to the host 300 in response to an instruction received from the processor 260.

The NAND interface circuit 220 is connected to the NAND flash memory 100 via the NAND bus, and controls communication with the NAND flash memory 100. The NAND interface circuit 220 outputs a signal to the NAND flash memory 100 based on the instruction received from the processor 260. During a write process (also referred to as a write operation), the NAND interface circuit 220 transfers a program command and a program target address issued by the processor 260 and write data in the buffer memory 240 to the NAND flash memory 100. During a read process (also referred to as a read operation), the NAND interface circuit 220 transfers a sense command and a sense target address issued by the processor 260 to the NAND flash memory 100. Furthermore, the NAND interface circuit 220 receives read data from the NAND flash memory 100 and transfers it to the buffer memory 240.

The main memory 230 may be, for example, a static random access memory (SRAM) or a dynamic random access memory (DRAM). The main memory 230 temporarily stores, for example, firmware for managing the NAND flash memory 100, an address table AT, a word line group allocation table WT, a shift table ST, and a history value table HT. The address table AT is a table for managing a storage designation address (logical address) of data designated by the host 300 and the location (physical address) in the NAND flash memory 100 corresponding to this storage destination address. Details of the word line group allocation table WT, the shift table ST, and the history value table HT will be described later.

The buffer memory 240 is, for example, a DRAM. The buffer memory 240 temporarily stores write data and read data.

The ECC circuit 250 performs an error correction encoding process or an error correction decoding process on data. These are processes necessary for detecting and correcting errors of data. Specifically, in a write process, the ECC circuit 250 performs an error correction encoding process on data to be written to the NAND flash memory 100. In the error correction encoding process, data including information for error correction is generated from write data based on an error correction code generation method. In a read process, the ECC circuit 250 performs an error correction decoding process on data read from the NAND flash memory 100. In the error correction decoding process, the ECC circuit 250 detects errors in the read data and attempts to correct an error if there is an error.

The processor 260 controls the operation of the entire memory controller 200. The processor 260 is, for example, a central processing unit (CPU). The processor 260 executes various processes, for example, by executing firmware.

The processor 260 includes a cache memory 270. The cache memory 270 is, for example, an SRAM. The processor 260 accesses the cache memory 270 at a speed higher than that when accessing the main memory 230, and the processor 260 uses the cache memory 270 as a work area in various processes. The processor 260 transfers, for example, at least some of various tables, which are stored in the main memory 230, to the cache memory 270 and uses them to execute various processes. Hereinafter, the processor 260 transferring data stored in the main memory 230 to the cache memory 270 may be simply described as “the processor 260 acquiring data”.

The cache memory 270 includes a plurality of cache lines. Each of the cache lines is a memory area capable of storing a predetermined number of bits (for example, 512 bits) of data. Hereinafter, the size of data that can be stored in one cache line may be referred to as a cache line size.

For example, the processor 260 accesses the main memory 230 in units of memory areas each having a cache line size to acquire data from the main memory 230. The data acquired from the memory area is stored in the cache line. In this case, for example, when a plurality of pieces of data are stored in the memory area of the main memory 230, the processor 260 can acquire the plurality of pieces of data by accessing the main memory 230 once.

The cache memory 270 may be provided outside the processor 260.

The processor 260 functions as a write control unit 262, a read control unit 264, and an erase control unit 266. The processor 260 functions as each of these units, for example, by executing firmware.

The write control unit 262 performs processing for writing data to the NAND flash memory 100 based on a write request received from the host 300. Specifically, when the write control unit 262 receives the write request, the write control unit 262 determines a location (program target address) in the NAND flash memory 100 where the write data is to be stored. The program target address includes, for example, a block address and a page address. The write control unit 262 instructs the NAND flash memory 100 to execute a program operation of the write data at the program target address via the NAND interface circuit 220. The write control unit 262 also updates the address table AT stored in the main memory 230. Specifically, the write control unit 262 updates the address table AT to associate, for example, a logical address at which the write request is received (write request address) with a physical address at which the write data is stored (program target address).

The read control unit 264 performs processing for reading data from the NAND flash memory 100 based on a read request received from the host 300. Specifically, when the read control unit 264 receives the read request, the read control unit 264 determines a physical address (sense target address) corresponding to a logical address (read request address) at which the read request is received with reference to the address table AT. The sense target address includes, for example, a block address and a page address. The read control unit 264 also determines a read method to be executed in the read process. In the read process, the read control unit 264 instructs the NAND flash memory 100 to execute a sense operation at the sense target address via the NAND interface circuit 220. Details of the read method will be described later. The series of processes performed by the memory system 1 after receiving the read request from the host 300 may be referred to as a read sequence.

The erase control unit 266 performs processing for erasing data in the NAND flash memory 100 based on, for example, a request received from the host 300. Specifically, when the erase control unit 266 is requested to erase data, the erase control unit 266 determines a location (erase target address) in the NAND flash memory 100 to be subjected to an erase process (also referred to as an erase operation) with reference to the address table AT. The erase control unit 266 instructs the NAND flash memory 100 to perform data erase operation at the erase target address.

The above-mentioned write request, read request, and erase request are not limited to requests received from the host 300. That is, these requests also include a write request, a read request, and an erase request that occur in conjunction with the execution of other processes such as garbage collection (compaction), refresh, and patrol read.

### 1.3 Configuration of Nand Flash Memory

Next, a configuration of the NAND flash memory 100 will be described. As shown in FIG. 1, the NAND flash memory 100 includes a memory cell array 110 and a peripheral circuit 120.

The memory cell array 110 stores data given by the memory controller 200. The memory cell array 110 includes a plurality of blocks BLK each including a plurality of nonvolatile memory cells each of which is associated with a row and a column. Data stored in the memory cell array 110 is erased in units of blocks BLK. In FIG. 1, four blocks BLK0 to BLK3 are shown as an example. A target block BLK for various operations is designated by a block address included in an address ADD received from the memory controller 200.

The peripheral circuit 120 performs a program operation of write data to the memory cell array 110 based on a program command received from the memory controller 200. The peripheral circuit 120 also performs a sense operation of data from the memory cell array 110 based on a sense command received from the memory controller 200, and transfers the sensed data to the memory controller 200 as read data.

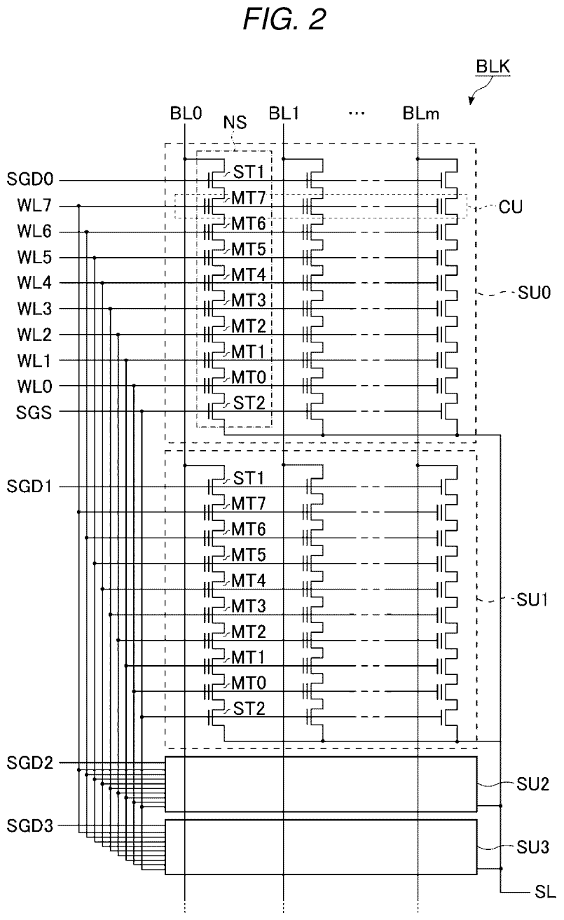

Next, a circuit configuration of the block BLK will be described with reference to FIG. 2. FIG. 2 is a circuit diagram of one of the blocks BLK.

As shown in FIG. 2, the block BLK includes, for example, four string units SU (SU0 to SU3). Each string unit SU includes a plurality of NAND strings NS.

Each of the NAND strings NS includes, for example, eight memory cell transistors MT (MT0 to MT7) and select transistors ST1 and ST2. The memory cell transistor MT includes a control gate and a charge storage layer, and stores data in a nonvolatile manner. The memory cell transistor MT is connected in series between the source of the select transistor ST1 and the drain of the select transistor ST2. Each memory cell transistor MT can store not only one bit of data, but also two or more bits of data.

The gates of the select transistors ST1 in the plurality of NAND strings NS of each of the string units SU0 to SU3 are connected to select gate lines SGD0 to SGD3, respectively. On the other hand, the gates of the select transistors ST2 in the plurality of NAND strings NS of each of the string units SU0 to SU3 are connected in common to, for example, a select gate line SGS. Alternatively, the gates of the select transistors ST2 in the plurality of NAND strings NS in each of the string units SU0 to SU3 may be connected to select gate lines SGS0 to SGS3 (not shown) that are different for each string unit. In addition, control gates of the memory cell transistors MT0 to MT7 in the plurality of NAND strings NS in the same block BLK are connected in common to word lines WL0 to WL7, respectively.

In addition, the drains of the select transistors ST1 of the NAND strings NS in the same column which are included in the plurality of blocks BLK in the memory cell array 110 are connected in common to a bit line BL (BL0 to BLm, where m is a natural number equal to or greater than 1). That is, the bit line BL connects in common the NAND strings NS in the same column across the plurality of blocks BLK. Furthermore, the sources of the plurality of select transistors ST2 are connected in common to a source line SL.

A set of the plurality of memory cell transistors MT included in the same string unit SU and connected to the same word line WL is referred to as, for example, a cell unit CU. The cell unit CU includes N pages, which are memory areas, in accordance with the number of bits N of cell data stored in each memory cell transistor MT. For example, one page stores a set of 1-bit data that are located at the same bit position in the cell data stored in each memory cell transistor MT of the cell unit CU. Below, the storage capacity of one page is referred to as a page size.

In a program operation of data for the memory cell array 110, for example, data stored in each of the N pages included in the cell unit CU is programmed into the cell unit CU at once. A sense operation of data from the memory cell array 110 is performed for each page. A page to be subjected to a program operation is designated by a program target address received from the memory controller 200. Hereinafter, a page designated as a target page of a program operation may be referred to as a program target page. In addition, a page to be subjected to a sense operation is designated by a sense target address received from the memory controller 200. Hereinafter, a page designated as a target page of a sense operation may be referred to as a sense target page.

The memory controller 200 may group the word lines WL in the memory cell array 110 into at least one group of word lines WL (hereinafter referred to as a word line group WLG) and perform various processes or data management with each word line group WLG as a unit.

The NAND flash memory 100 may have a circuit configuration other than that described above. For example, the number of blocks BLK in the NAND flash memory 100, the number of string units SU in the block BLK, and the number of memory cell transistors MT and the number of select transistors ST1 and ST2 in the NAND string NS may be designed to be any number. The NAND flash memory 100 may also have a three-dimensional NAND structure.

### 1.4 Threshold Voltage Distribution of Memory Cell Transistor MT

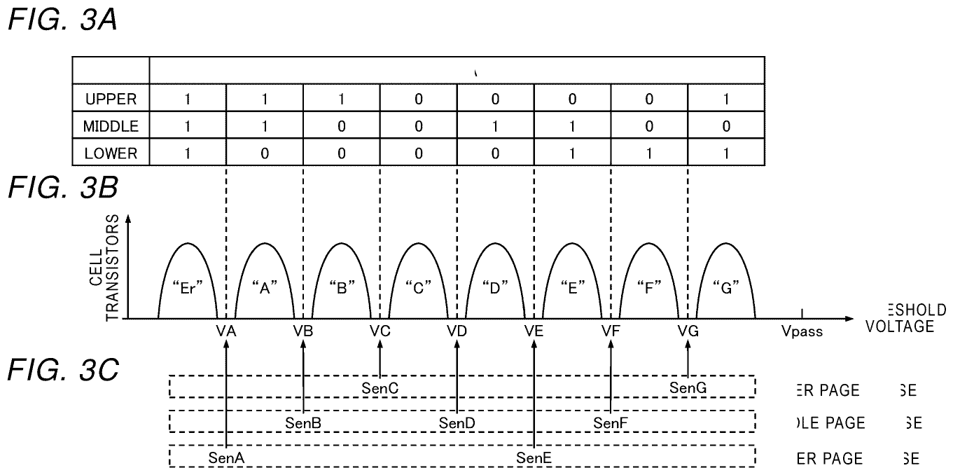

Next, a threshold voltage distribution of the memory cell transistor MT will be described using FIGS. 3A to 3C. FIGS. 3A to 3C show a threshold voltage distribution of the memory cell transistor MT according to this embodiment. FIG. 3A is a diagram showing an example of a bit allocation table that is set for the memory cell transistor MT using a triple level cell (TLC) method. The TLC method is a system in which three bits of data are stored in one memory cell transistor MT. FIG. 3B is a diagram showing an example of a threshold voltage distribution and a word line voltage of the memory cell transistor MT when programming is performed using the bit allocation shown in FIG. 3A. The vertical axis of the threshold voltage distribution shown in FIG. 3B corresponds to the number of memory cell transistors MT, and the horizontal axis corresponds to a threshold voltage of the memory cell transistor MT.

As shown in FIG. 3B, in the TLC method, a program operation is performed such that the plurality of memory cell transistors MT form eight threshold voltage distributions. Each state of the threshold voltage distribution (an Er state to a G state in FIG. 3B) is assigned the data as shown in FIG. 3A. Specifically, in the example of FIGS. 3A to 3C, 111 is assigned to the Er state, 110 is assigned to an A state, 100 is assigned to a B state, 000 is assigned to a C state, 010 is assigned to a D state, 011 is assigned to an E state, 001 is assigned to an F state, and 101 is assigned to the G state.

Hereinafter, the most significant bit of the data stored in the memory cell transistor MT using the TLC method will be referred to as an upper (UPPER) bit. In addition, among the pages included in the cell unit CU, a page in which a set of upper bits is stored is referred to as an upper page. In addition, the second most significant bit of the data stored in the memory cell transistor MT using the TLC method is referred to as a middle (MIDDLE) bit, and a page in which a set of middle bits is stored is referred to as a middle page. In addition, the least significant bit of the data stored in the memory cell transistor MT using the TLC method is referred to as a lower (LOWER) bit, and a page in which a set of lower bits is stored is referred to as a lower page.

Between adjacent threshold voltage distributions, a word line voltage to be used in each sense operation is set. Specifically, for example, a word line voltage VA for determining whether the threshold voltage of the memory cell transistor MT is included in the Er state or is included in the A state or higher is set between the Er state and the A state. Hereinafter, a sense operation for determining whether the threshold voltage of the memory cell transistor MT is included in the Er state or is included in the A state or higher will be referred to as an A state sense SenA. In the A state sense SenA, the word line voltage VA is used. Similarly, a word line voltage VB is set between the A state and the B state and is used in a B state sense SenB. In addition, a word line voltage VC is set between the B state and the C state and is used in a C state sense SenC. In addition, a word line voltage VD is set between the C state and the D state and is used in a D state sense SenD. In addition, a word line voltage VE is set between the D state and the E state and is used in an E state sense SenE. In addition, a word line voltage VF is set between the E state and the F state and is used in an F state sense SenF. In addition, a word line voltage VG is set between the F state and the G state and is used in a G state sense SenG. In addition, a sense pass voltage Vpass is set to a voltage value higher than the maximum threshold voltage in the highest threshold voltage distribution (for example, G state). The memory cell transistor MT connected to the word line WL to which the sense pass voltage Vpass is applied is set to be in an ON state regardless of its programmed data.

In a sense operation, the peripheral circuit 120 applies a selected word line voltage Vsel to a word line WL corresponding to a sense target address (hereinafter referred to as a selected word line SelWL) in order to determine the state to which each memory cell transistor MT configuring a sense target page belongs. Here, as shown in FIG. 3C, in the sense operation, a set of word line voltages configured with different word line voltages is used as the selected word line voltage Vsel in accordance with a page type of the sense target page. Specifically, for example, in a sense operation of an upper page, a set of word line voltages having the word line voltage VC and the word line voltage VG is used as the selected word line voltage Vsel in order to distinguish an upper bit of the data stored in the memory cell transistor MT. Further, in a sense operation of a middle page, a word line voltage set having the word line voltage VB, the word line voltage VD, and the word line voltage VF is used to distinguish a middle bit of the data stored in the memory cell transistor MT. Further, in a sense operation of a lower page, a word line voltage set having the word line voltage VA and the word line voltage VE is used to distinguish a lower bit of the data stored in the memory cell transistor MT.

Hereinafter, a word line WL corresponding to a program target address in a program operation may also be referred to as a selected word line SelWL.

### 1.5 Read Method

Next, a read method executed in the memory system according to this embodiment will be described.

As described above, the Er state to the G state can be distinguished by a sense operation using the word line voltages VA to VG. However, when a threshold voltage distribution of the memory cell transistor MT changes due to factors such as the elapse of time, a temperature, and read disturbance after data is programmed, the data may not be sensed correctly under fixed sense conditions (for example, voltage values of the word line voltages).

In preparation for such a case, the memory controller 200 is configured to execute several read methods with a change in a sense condition. Specifically, the change in the sense condition is, for example, a shift of the word line voltage. The memory controller 200 can execute, for example, learning read and history value read as read methods accompanying the shift of the word line voltage. However, the read methods that can be executed by the memory controller 200 are not limited thereto. In this embodiment, changing the word line voltage is referred to as shifting the word line voltage. In addition, the amount of voltage that is shifted is referred to as a shift amount. In addition, hereinafter, a read process based on learning read may be simply referred to as learning read. Similarly, a read process based on history value read may be simply referred to as history value read.

The learning read is a read method of reading data while learning a word line voltage that results in a successful sense operation or successful read process. The “successful read process” means that data correctly sensed is acquired as read data in the read process. A “successful read process” means a read process that completes without a read error. A “successful sense operation” means that the read data sensed during the sense operation matches the original data or the original data can be restored from the read data by executing an error correction decoding process on the read data by the ECC circuit 250. In the learning read, for example, the memory controller 200 performs a sense operation using a shifted word line voltage as the selected word line voltage Vsel at least once, and learns a shift amount of the word line voltage when the sense operation is successful as a history value for the selected word line SelWL. The history value becomes a candidate for a shift amount of a word line voltage applied to the selected word line SelWL in a later sense operation. The learned history value is stored, in association with the selected word line SelWL, in the history value table HT.

In this embodiment, a case where the memory controller 200 performs learning read using the shift table ST as learning read will be described as an example. The shift table ST is a table for managing a set of information representing a shift amount of a word line voltage used in a sense operation.

The history value read is a read method in which a word line voltage shifted based on a history value learned in learning read is used as the selected word line voltage Vsel. In this embodiment, the memory controller 200 can use a history value learned for a certain word line WL as a history value for a unit of a larger area. For example, the word line group WLG is used as an area in which the history value is shared. In this embodiment, description is given of an example in which the memory controller 200 uses a history value learned for a certain word line WL as a history value for a word line group WLG that includes the certain word line WL.

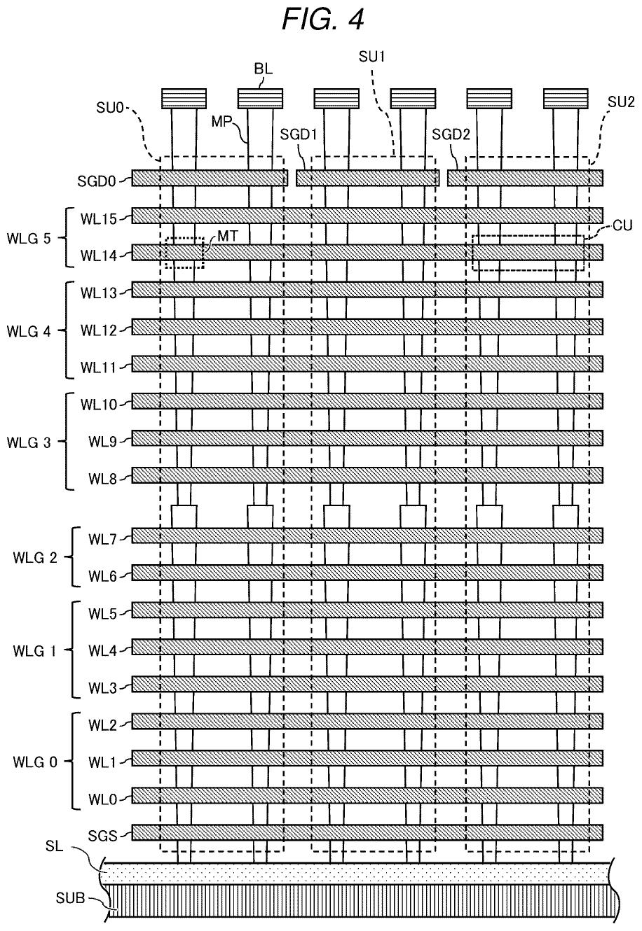

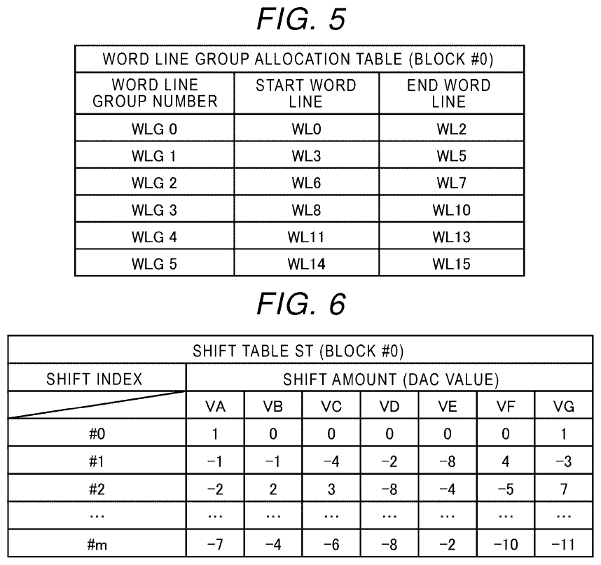

Here, an example of grouping of the word line group WLG will be described with reference to FIGS. 4 and 5. FIG. 4 is a diagram showing an example of grouping of the word line group WLG when the memory cell array 110 has a 16-layer three-dimensional NAND structure. FIG. 5 is an example of a word line group allocation table WT corresponding to the grouping of the word line group WLG shown in FIG. 4. In the learning read and history value read, the memory controller 200 specifies a word line group WLG including word lines WL with reference to the word line group allocation table WT as shown in FIG. 5. In the example of FIGS. 4 and 5, word lines WL0 to WL2 are grouped into a word line group WLG0, word lines WL3 to WL5 are grouped into a word line group WLG1, word lines WL6 to WL7 are grouped into a word line group WLG2, word lines WL8 to WL10 are grouped into a word line group WLG3, word lines WL11 to WL13 are grouped into a word line group WLG4, and word lines WL14 to WL15 are grouped into a word line group WLG5.

In a memory cell array having a three-dimensional NAND structure, memory cells connected to two word lines WL that are close to each other in a stacking direction of the word lines WL have a characteristic that their threshold voltage distribution changes tend to become similar to each other. Thus, the memory controller 200 uses, for example, a history value acquired in learning read for the word line WL0 as a history value for the word line WL1 or the word line WL2, and thus data can be reliably sensed from a page corresponding to these word lines WL. In this manner, the memory controller 200 can increase the reliability of history value read by diverting history values by grouping the word lines WL in the word line group WLG so that each of the word lines WL is adjacent to one of the other word lines WL in the word line group WLG. In this description, when two elements are “adjacent”, this does not necessarily mean that the elements are in contact with each other.

In the grouping of the word lines WL into the word line group WLG, the word lines WL grouped into the same word line group WLG do not necessarily have to be adjacent to each other. That is, the grouping of the word lines WL into the word line group WLG can be set freely from the viewpoint of the characteristics of each word line WL and the characteristics of memory cells connected to each word line WL. In addition, the word lines WL may be grouped such that the number of word lines WL in each word line group WLG is uniform. In addition, the configuration of the word line group WLG may be different for each block BLK. Hereinafter, the number of word lines WL in the word line group WLG may be expressed as a quantity in word line group Nwl.

In FIG. 4, SUB represents a substrate. Further, in FIG. 4, each MP represents a memory pillar. For example, each memory pillar MP extends in a direction perpendicular to the substrate SUB. In addition, for example, as shown in FIG. 4, the word lines WL are stacked to be spaced apart from each other in a direction perpendicular to the substrate SUB. In addition, as shown in FIG. 4, an intersection of the memory pillar MP and the word line WL is the general location of the memory cell transistor MT. The other reference numerals in FIG. 4 are as described using FIG. 2.

Further, in the configuration shown in FIG. 4, for example, data is programmed into the memory cells connected to each word line WL in the order of stacking of the word lines WL (that is, WL0, WL1, . . . WL15). In this embodiment, for simplicity, in each block BLK, the order of stacking of the word lines WL corresponds to a word line number, and data is programmed into the memory cells connected to the word lines WL in ascending order of the word line numbers.

In FIG. 5, the word lines WL in each word line group WLG are defined by a start word line and an end word line, but this is not limiting. That is, in the word line group allocation table WT, the word lines WL in each word group may be defined by the start word line and the number of word lines WL. In addition, the word line numbers in the word line group WLG may be listed and stored.

Next, determination of a read method will be described. The read control unit 264 determines a read method to be executed in a read process. Here, learning read is more reliable than history value read, but it takes longer to complete the learning read than the history value read. Thus, when a read request is received, the read control unit 264 first selects history value read using a history value available for the selected word line SelWL as a candidate read method, and determines whether to execute the history value read. Then, when the read control unit 264 determines to execute the history value read in the determination regarding whether to execute history value read, the read control unit 264 executes a read process based on the history value read. On the other hand, when the read control unit 264 determines to skip history value read in the determination regarding whether to execute history value read, the read control unit 264 skips the history value read and executes a read process based on the learning read. The “high reliability” means that a bit error rate of sensed data is lower.

In the determination regarding whether to execute history value read, the read control unit 264 refers to, for example, the program status of data for the memory cell in the block BLK to be read. Hereinafter, when data is already programmed into a memory cell, the memory cell is said to be “has been programmed”. For example, when a program operation for one memory cell is performed in at least two or more steps, “has been programmed” may refer to a state in which the program operation of data into the memory cell is completed, or may refer to a state in which at least one step of program operation is performed on the memory cell. In addition, a program state can also be defined individually in accordance with the number of bits of data written to the memory cell. Hereinafter, when all memory cells connected to a certain word line WL have been programmed, it may be simply said that the word line WL has been programmed. Hereinafter, when all word lines in a certain word line group WLG have been programmed, it may be simply said that the word line group WLG has been programmed.

When programming for a block BLK is in progress, that is, when the block BLK includes a memory cell that has not been programmed, in the block BLK, an effective threshold voltage of the memory cell connected to the word line WL, for example, near the memory cell that has not been programmed, may change. In such a case, the reliability of history value read using a history value may decrease. In a read sequence in which a page corresponding to such a word line WL is set as a sense target page, the read control unit 264 skips history value read. Hereinafter, in this embodiment, description is given of an example in which the read control unit 264 refers to the program status of the memory cell connected to the word line WL adjacent to the selected word line SelWL in the determination regarding whether to execute history value read. Hereinafter, memory cells connected to a word line WL adjacent to a certain word line WL may be referred to as peripheral memory cells of the certain word line WL.

Here, as a method for the memory controller 200 to manage the program status of peripheral memory cells of each word line WL, it is conceivable to store a table in the main memory 230. However, in a configuration in which the history value table HT and a table regarding the program status of the peripheral memory cells are stored in different memory areas in the main memory 230 (particularly, two or more memory areas in which the processor 260 cannot acquire data collectively in one cache line), a cache line corresponding to the number of blocks in the NAND flash memory 100 or a memory area in the main memory 230 is occupied to store the program status of the peripheral memory cells. Further, in such a configuration, after the read control unit 264 determines to execute history value read with reference to the program status of the peripheral memory cells, the read control unit 264 may have to access the main memory 230 separately to acquire a history value, leading to an increase in latency.

Consequently, in the memory system according to this embodiment, the memory controller 200 stores the program status of the peripheral memory cells and history values in memory areas in the main memory 230 where data can be acquired collectively into the same cache line. Specifically, the memory controller 200 stores the program status and history values of the peripheral memory cells in memory areas in the main memory 230 which have, for example, a size equal to or smaller than the cache line size, and have consecutive addresses. Thereby, it is possible to curb an increase in latency due to a plurality of accesses to the main memory 230. In addition, it is possible to reduce the number of cache lines reserved for storing the program status. In this embodiment, the memory controller stores the program status of the peripheral memory cells and the history values in the history value table HT.

Hereinafter, memory areas in the main memory 230 where data can be acquired collectively into the same cache line in the cache memory 270 may be referred to as aligned areas. That is, when the processor 260 acquires data from the main memory 230, the processor 260 accesses the main memory 230 in units of aligned areas. The aligned areas may be fixed memory areas associated with cache lines, or may be dynamic with respect to the cache lines.

In addition, the processor 260 does not necessarily have to update the history value table HT stored in the main memory 230 every time at least a portion of information stored in the history value table HT is updated. That is, for example, when the program status is updated, only the program status stored in the cache line in the cache memory 270 may be updated, and the program status update may then be reflected in the history value table HT stored in the main memory 230 at an appropriate time.

### 1.6 Regarding Management Table

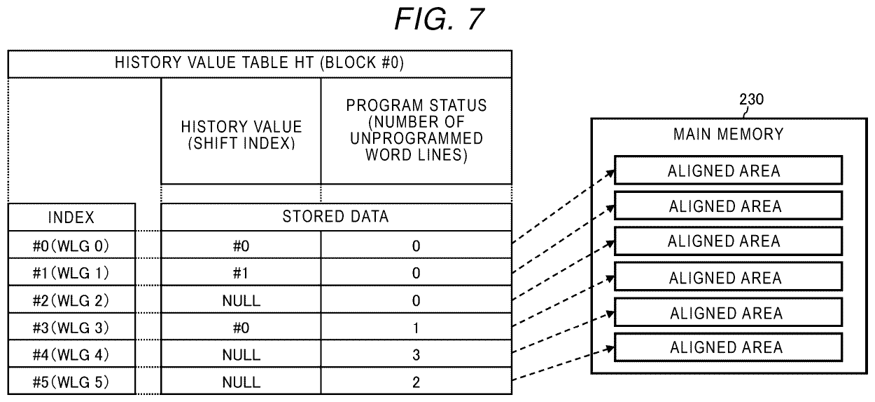

Next, details of various management tables used in the memory system according to this embodiment will be described with reference to FIGS. 6 and 7.

1.6.1 Shift table

FIG. 6 is a diagram showing an example of the shift table ST used in the memory system according to this embodiment. The shift table ST is stored in the main memory 230. The shift table ST is managed, for example, for each block BLK. A common shift table ST may be used between a plurality of blocks BLK. In the example of FIG. 6, the shift table ST for block #0 is shown. As shown in FIG. 6, each shift table ST has m+1 entries. Here, m is an integer equal to or greater than 1. The number of entries in the shift table ST may be different for each block BLK. An index of #0 to #m (hereinafter referred to as a shift index) is assigned to each entry. Each entry stores information on shift amounts of the word line voltages VA to VG. In the example of FIG. 6, each entry stores a voltage level value (hereinafter referred to as a DAC value) that corresponds to the shift amount of the word line voltage. That is, in a read process, the shift index in the shift table ST is determined, which means that a shift amount of a word line voltage used in a sense operation is determined.

In learning read using the shift table ST, the memory controller 200 performs a read process using the DAC value associated with the shift index in ascending order of the shift indexes in the shift table ST (in the order of #0, #1, #2, . . . ). Specifically, the memory controller 200 instructs the NAND flash memory 100 to perform a sense operation using the DAC value associated with the selected shift index. Then, the memory controller 200 learns, as a history value, a shift index when the sense operation is successful. The learned history value is stored in the history value table HT.

In the example of FIG. 6, shift amounts of the word line voltages VA to VG are associated with indexes, but this is not limiting. That is, for example, a shift amount of a word line voltage set used for sensing any one of a lower page, a middle page, or an upper page may be associated with each index. In this case, the memory controller 200 can learn a history value for each page, for example. In addition, when the memory controller 200 learns a history value for each page, the memory controller 200 can divert a history value, which is learned for a certain page type (for example, a lower page), for another page type (for example, an upper page).

In addition, the information on the shift amounts stored in the shift table ST may be a fixed value that is set in advance, or may be changed depending on a result of learning read or the like.

### 1.6.2 History Value Table

FIG. 7 is a diagram showing an example of the history value table HT used in the memory system according to this embodiment. In particular, FIG. 7 shows an example of the history value table HT in the configuration of the word line group WLG shown in FIGS. 4 and 5. The history value table HT is stored in the main memory 230. The history value table HT is managed, for example, for each block BLK, and has entries corresponding to the number of word line groups WLG grouped in the block BLK, each of which is assigned an index. In this embodiment, the index is the word line group number corresponding to each entry.

Each entry of the history value table HT stores a history value and a program status related to the word line group WLG. In this embodiment, a shift index is stored as the history value. In addition, as the program status related to the word line group WLG, the program status of the word line WL in the word line group WLG is stored. More specifically, the number of unprogrammed word lines WL among the word lines WL in the word line group WLG is stored as the program status related to the word line group WLG. Hereinafter, in this embodiment, the number of unprogrammed word lines WL among the word lines WL in a certain word line group WLG is referred to as the number of unprogrammed word lines NupWL for the certain word line group WLG.

in FIG. 7, “NULL” indicates that no data exists. That is, in the example in FIG. 7, there is no history value corresponding to index #2, which indicates that no history value has been acquired by learning read for any of the word lines WL in the word line group WLG2.

In this embodiment, the number of unprogrammed word lines NupWL can be an integer value of equal to or greater than 0 and equal to or less than the quantity in word line group Nwl. When the number of unprogrammed word lines NupWL is 0, it indicates that all of the word lines WL in the word line group WLG have been programmed. In addition, when the number of unprogrammed word lines NupWL is equal to the quantity in word line group Nwl, it indicates that none of the word lines WL in the word line group WLG have been programmed.

For example, when a program operation in which one of the word lines WL in a certain word line group WLG is the selected word line SelWL is performed, the memory controller 200 decrements the number of unprogrammed word lines NupWL corresponding to the certain word line group WLG by 1. In this embodiment, the memory controller 200 may consider that “a program operation has been performed” when “a program command has been transmitted to the NAND flash memory 100”.

When a block BLK has been erased, the number of unprogrammed word lines NupWL stored in the history value table HT corresponding to the block BLK is equal to the corresponding quantity in word line group Nwl. That is, when an erase operation is performed on a block BLK, the program status stored in the history value table HT corresponding to the block BLK is initialized to the quantity in word line group Nwl. In addition to initializing the program status, all history values stored in the history value table HT may be initialized to “NULL”. These initialization processes are performed, for example, by the erase control unit 266.

The example in FIG. 7 corresponds to a state in which the word lines WL0 to WL9 have been programmed in the configuration of the word line group WLG as shown in FIGS. 4 and 5. For the word line groups WLG0 to WLG2, the number of unprogrammed word lines NupWL is 0, which indicates that all word lines WL (WL0 to WL7) in the word line groups WLG0 to WLG2 have been all programmed. For the word line group WLG3, the word lines WL8 and WL9 have been programmed except for WL10, which is the last one in ascending order of word line number, among the word lines WL8 to WL10. In addition, for the word line groups WLG4 and WLG5, the number of unprogrammed word lines NupWL is equal to the quantity in word line group Nwl, which indicates that none of the word lines WL (WL11 to WL15) in the word line groups WLG4 and WLG5 have been programmed.

Hereinafter, a word line WL that has been programmed last in a block BLK in the middle of programming, such as the word line WL9 in the example of FIG. 7, may be referred to as an edge word line or an edge WL. Peripheral memory cells of an edge word line include at least memory cells that have not been programmed. Hereinafter, in this embodiment, the read control unit 264 determines whether the selected word line SelWL is an edge word line in the determination regarding whether to execute history value read. When the selected word line SelWL is an edge word line, the read control unit 264 skips the execution of history value read in the read sequence.

As shown in FIG. 7, each entry in the history value table HT corresponds to one aligned area. That is, as described above, pieces of data corresponding to the entries (history value and program status) are stored in the same aligned area in the main memory 230. There may be a plurality of entries corresponding to one aligned area. In this case, the pieces of data corresponding to the plurality of entries are stored in one aligned area.

In FIG. 7, a NULL value is stored as a value indicating that no history value exists, but this is not limiting. That is, the memory controller 200 may manage flags indicating whether a history value exists in each word line group WLG by using a table such as the word line group allocation table WT, and store data in the history value table HT only for the word line groups WLG that include a history value or a program status.

In addition, each entry in the history value table HT may collectively store, for example, history values and program statuses corresponding to the word line groups WLG for the plurality of blocks BLK. In this case, for example, one history value table HT is stored for a block group in which the plurality of blocks BLK are collected. Then, each entry in the history value table HT corresponding to a certain block group stores the same number of history values and program statuses as the number of blocks BLK in the certain block group for the word line group WLG corresponding to the entry.

Further, in FIG. 7, a shift index is stored as the history value, but this is not limiting. That is, for example, a voltage value or a shift amount of a word line voltage may be stored as the history value. In addition, depending on a sense condition learned in the learning read, information capable of specifying the sense condition may be stored as a history value in the history value table HT.

Further, in FIG. 7, the number of unprogrammed word lines is stored as the program status for the word line group WLG, but this is not limiting. That is, for example, the number of programmed word lines WL in the word line group WLG may be stored as the program status. Alternatively, the word line number of the word line WL that has been programmed last in the word line group WLG, or information listing whether each word line WL has been programmed may be stored as the program status. The program status stored in the history value table HT may be any information that can specify the program status of peripheral memory cells for each word line WL in the word line group WLG.

### 1.7 Operation

Next, the operation of the memory system according to this embodiment will be described.

### 1.7.1 Read Sequence

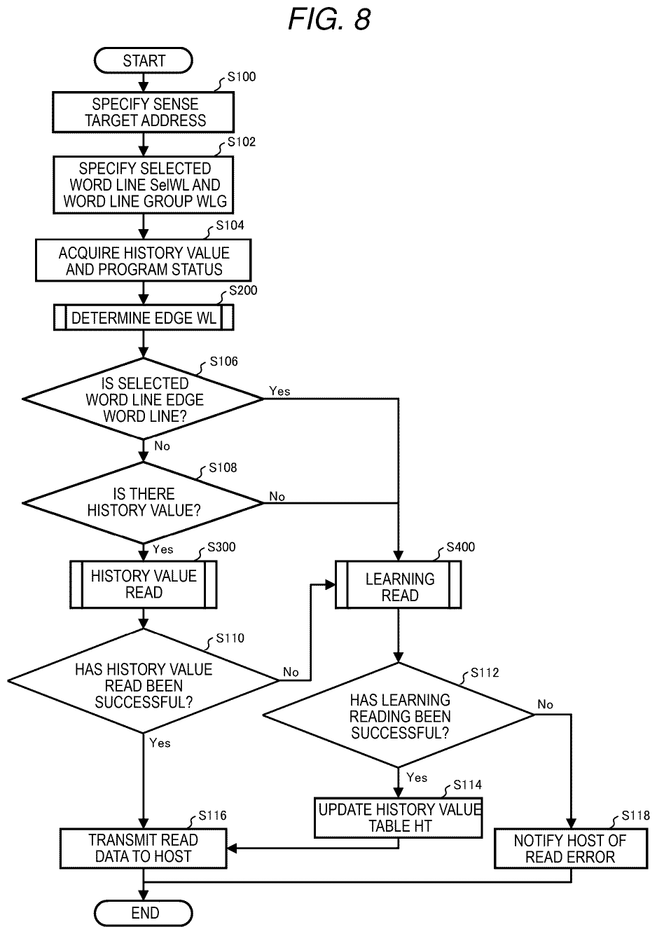

First, an example of a read sequence in this embodiment will be described with reference to FIG. 8. The memory controller 200 starts the read sequence, for example, by receiving a data read request from the host 300.

In step S100, the memory controller 200 specifies a sense target address from a read request address received from the host 300. The memory controller 200 specifies the sense target address, for example, with reference to the address table AT. The read request address is received from the host 300 following the read request or by being included in the read request.

In step S102, the memory controller 200 specifies a word line number of the selected word line SelWL and the corresponding word line group WLG (hereinafter also referred to as a target word line group) based on the sense target address specified in step S100. For example, the memory controller 200 specifies a word line group allocation table WT to be referred to from a block address included in the sense target address, and specifies the word line group WLG with reference to the specified word line group allocation table WT.

In step S104, the memory controller 200 acquires a history value and program status of the word line group WLG specified in step S102 with reference to the history value table HT. Specifically, in this embodiment, the memory controller 200 acquires a shift index as the history value and acquires the number of unprogrammed word lines NupWL as the program status. The memory controller 200 specifies a history value table HT to be referred to, for example, from the block address included in the sense target address.

In step S200, the memory controller 200 determines whether the selected word line SelWL is an edge word line (hereinafter, also referred to as edge word line determination) based on the number of unprogrammed word lines NupWL acquired in step S104. Details of the edge word line determination will be described later. When the result of the edge word line determination shows that the selected word line SelWL is an edge word line (Yes in step S106), this operation proceeds to step S400. On the other hand, when the result of the edge word line determination shows that the selected word line SelWL is not an edge word line (No in step S106), this operation proceeds to step S108.

In step S108, the memory controller 200 determines whether a history value exists for the target word line group. The memory controller 200 determines whether the value of the history value acquired in step S104 is a NULL value, for example. When the acquired history value is not a NULL value, that is, when a history value exists for the target word line group (Yes in step S108), this operation proceeds to step S300. On the other hand, when the acquired history value is a NULL value, that is, when history value does not exist for the target word line group (No in step S108), this operation proceeds to step S400.

In step S300, the memory controller 200 executes history value read based on the history value acquired in step S104. Details of the history value read will be described later. Read data received from the NAND flash memory 100 during the history value read is temporarily stored in, for example, the buffer memory 240. When the memory controller 200 succeeds in the history value read (Yes in step S110), this operation proceeds to step S116. On the other hand, when the memory controller 200 does not succeed in the history value read (No in step S110), this operation proceeds to step S400.

In step S400, the memory controller 200 executes learning read. Details of the learning read will be described later. The read data received from the NAND flash memory 100 in the learning read is temporarily stored in, for example, the buffer memory 240. When the memory controller 200 succeeds in the learning read (Yes in step S112), this operation proceeds to step S114. On the other hand, when the memory controller 200 does not succeed in the learning read (No in step S112), a read error is notified to the host 300 (step S118), and this operation ends.

In step S114, the memory controller 200 updates the history value table HT based on the history value learned in step S400. Specifically, the memory controller 200 stores, for example, the shift index, which is acquired as the history value in the learning read in step S400, in an entry corresponding to a target word line group in the history value table HT.

In step S116, the read data is transmitted to the host 300, and this operation ends.

In step S114, the memory controller 200 may determine whether to update the history value table HT depending on whether the selected word line SelWL having been subjected to the learning read is an edge word line. That is, for example, when the selected word line SelWL is an edge word line, the memory controller 200 may not update the history value table HT with the learned history value, and when the selected word line SelWL is not an edge word line, the memory controller 200 may update the history value table HT with the learned history value.

### 1.7.1.1 Edge Word Line Determination

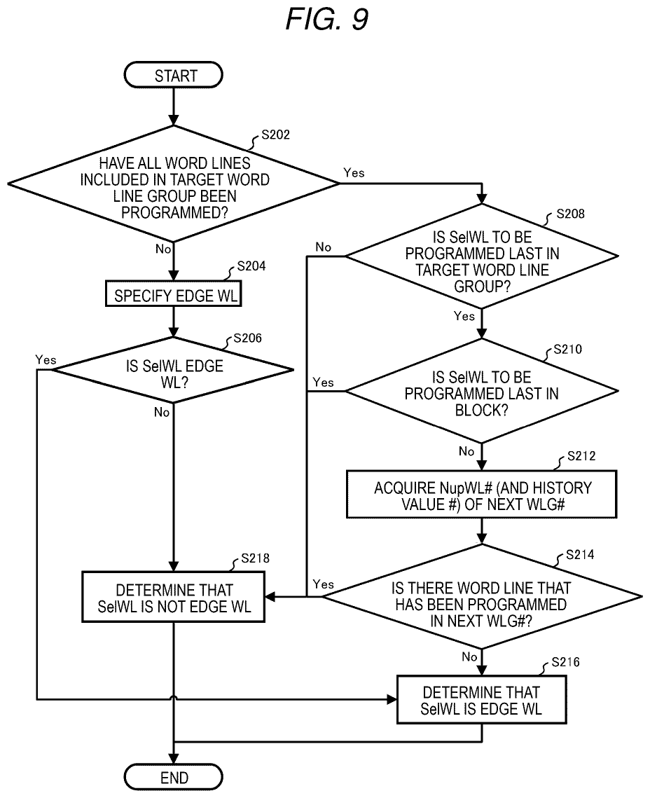

Next, a specific example of a flow of edge word line determination in this embodiment will be described with reference to FIG. 9. FIG. 9 particularly shows a flow of edge word line determination when the history value table HT described with reference to FIG. 7 is used. The following steps S202 to S218 are a flow equivalent to step S200 in FIG. 8.

When the edge word line determination starts, the read control unit 264 determines in step S202 whether all word lines WL in a target word line group have been programmed. Specifically, for example, the read control unit 264 determines whether the acquired number of unprogrammed word lines NupWL is 0. When the acquired number of unprogrammed word lines NupWL is 0, that is, when all of the word lines WL in the target word line group have been programmed (Yes in step S202), this operation proceeds to step S208. On the other hand, when the acquired number of unprogrammed word lines NupWL is not 0, that is, when there is a word line WL that has not been programmed among the word lines WL in the target word line group (No in step S202), this operation proceeds to step S204.

In step S204, the read control unit 264 specifies an edge word line in a block BLK to be sensed. Specifically, for example, the read control unit 264 specifies a word line number of the edge word line as Edge WL Number=WLGmax−NupWL. Here, WLGmax is a word line number of the end word line of the target word line group.

In step S206, the read control unit 264 determines whether the selected word line SelWL is the edge word line specified in step S204. Specifically, for example, the read control unit 264 determines whether the relation of SelWL Number=Edge WL Number is satisfied. When the relation of SelWL Number=Edge WL Number is satisfied, that is, when the selected word line SelWL is the edge word line specified in step S204 (Yes in step S206), this operation proceeds to step S216. On the other hand, when the relation of SelWL Number=Edge WL Number is not satisfied, that is, when the selected word line SelWL is not the edge word line specified in step S204 (No in step S206), this operation proceeds to step S218.

In step S208, the read control unit 264 determines whether the selected word line SelWL is a word line WL that is to be programmed last in the target word line group in pre-determined program order of word lines WL. Specifically, for example, the read control unit 264 determines whether the relation of SelWL Number=WLGmax is satisfied. When the relation of SelWL Number=WLGmax is satisfied, that is, when the selected word line SelWL is a word line WL that is to be programmed last in the target word line group (Yes in step S208), this operation proceeds to step S210. On the other hand, when the relation of SelWL Number=WLGmax is not satisfied, that is, when the selected word line SelWL is not a word line WL to be programmed last in the target word line group (No in step S208), this operation proceeds to step S218.

In step S210, the read control unit 264 determines whether the selected word line SelWL is a word line WL that is to be programmed last in the block BLK in pre-determined program order of word lines WL. Specifically, for example, the read control unit 264 determines whether the relation of SelWL Number=WLmax is satisfied. Here, WLmax is the word line number with the largest value among the word line numbers of the word lines WL in the block BLK. When the relation of SelWL Number=WLmax is satisfied, that is, when the selected word line SelWL is a word line WL that is to be programmed last in the block BLK (Yes in step S210), this operation proceeds to step S218. On the other hand, when the relation of SelWL Number=WLmax is not satisfied, that is, when the selected word line SelWL is not a word line WL that is to be programmed last in the block BLK (No in step S210), this operation proceeds to step S212.

In step S212, the read control unit 264 acquires the number of unprogrammed word lines NupWL (and history value) of the next word line group WLG # of the target word line group with reference to the history value table HT. The next word line group WLG # of the target word line group is a word line group WLG including the word lines WL that are to be programmed next after the target word line group. In the following, similarly, a word line group WLG including word lines WL that are to be programmed next after a certain word line group WLG may be referred to as a next word line group WLG # of the certain word line group WLG. In step S212, specifically, when the target word line group is a word line group WLGn (n is an integer equal to or greater than 0), the read control unit 264 acquires the number of unprogrammed word lines NupWL (and history value) of a word line group WLG(n+1). Hereinafter, the acquired number of unprogrammed word lines NupWL and history value of the next word line group WLG # may be referred to as the number of unprogrammed word lines NupWL # and a history value #.

In step S214, the read control unit 264 determines whether there is a word line WL that has been programmed among word lines WL in the next word line group WLG # based on the number of unprogrammed word lines NupWL # acquired in step S212. Specifically, for example, the read control unit 264 determines whether NupWL # is smaller than Nwl #. Here, Nwl # is the number of word lines WL in the next word line group WLG #. When NupWL # is smaller than Nwl #, that is, when there is a word line WL that has been programmed among the word lines WL in the next word line group WLG # (Yes in step S214), this operation proceeds to step S218. On the other hand, when NupWL # is not smaller than Nwl #, that is, when there is no word line WL that has been programmed among the word lines WL in the next word line group WLG # (No in step S214), this operation proceeds to step S216.

In step S216, the read control unit 264 determines that the selected word line SelWL is an edge word line, and this operation ends.

In step S218, the read control unit 264 determines that the selected word line SelWL is not an edge word line, and this operation ends.

In the above description, the read control unit 264 determines whether the selected word line SelWL is a word line WL that is to be programmed last in the block BLK (step S210), but this is not limiting. That is, for example, instead of the above determination, a step of determining whether a block BLK to be sensed has been programmed may be incorporated into the edge word line determination flow. In this case, the read control unit 264 may perform, for example, a step of determining whether the block BLK to be sensed has been programmed before step S202. When the block BLK to be sensed has been programmed, the read control unit 264 skips steps S202 to S206 and determines that the selected word line SelWL is not an edge word line. In this description, “block BLK has been programmed” means that all memory cells included in the block BLK have been programmed.

### 1.7.1.2 History Value Read

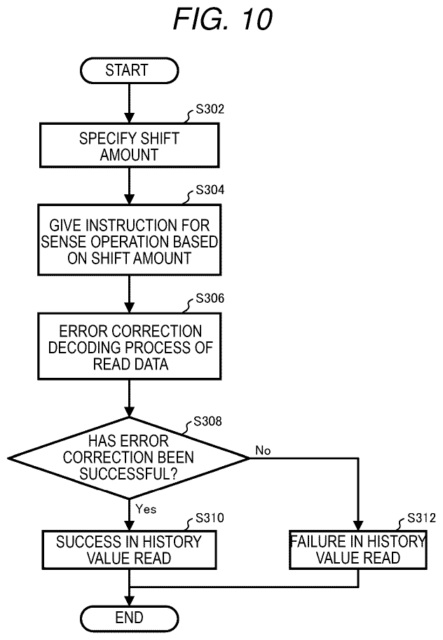

Next, a specific example of a flow of history value read in this embodiment will be described with reference to FIG. 10. FIG. 10 shows an example of a flow of history value read when the shift table ST described with reference to FIG. 6 and the history value table HT described with reference to FIG. 7 are used. The following steps S302 to S312 are equivalent to step S300 in FIG. 8.

In step S302, with reference to the shift table ST, the read control unit 264 specifies a shift amount corresponding to the shift index acquired as the history value in step S104 as described with reference to FIG. 8.

In step S304, the read control unit 264 instructs the NAND flash memory 100 to execute a sense operation based on the shift amount specified in step S302. Specifically, the read control unit 264 instructs the NAND flash memory 100 to execute a sense operation using the specified shift amount from a sense target address. In the instruction to execute the sense operation, the specified shift amount is transferred to the NAND flash memory 100 as a part of a sense command or together with the sense command. Read data sensed in the NAND flash memory 100 is transmitted to the memory controller 200 and temporarily stored in, for example, the buffer memory 240.

In step S306, the ECC circuit 250 performs error correction decoding process on the read data received from the NAND flash memory 100. When the ECC circuit 250 succeeds in the error correction decoding process (Yes in step S308), this operation proceeds to step S310. On the other hand, when the ECC circuit 250 fails in the error correction decoding process (No in step S308), this operation proceeds to step S312.

In step S310, the read control unit 264 determines that the history value read has been successful, and this operation ends.

In step S312, the read control unit 264 determines that the history value read has not been successful, and this operation ends.

### 1.7.1.3 Learning Read

Next, a specific example of a flow of learning read in this embodiment will be described with reference to FIG. 11. FIG. 11 shows an example of a flow of learning read, particularly when the shift table ST described with reference to FIG. 6 and the history value table HT described with reference to FIG. 7 are used. The following steps S402 to S416 are a flow equivalent to step S400 in FIG. 8.

In step S402, the read control unit 264 sets a shift index to the initial value in the shift table ST. In the example of FIG. 11, the shift index is set to 0.

In step S403, the read control unit 264 specifies a shift amount corresponding to the set shift index with reference to the shift table ST.

In step S404, the read control unit 264 instructs the NAND flash memory 100 to execute a sense operation based on the shift amount specified in step S403. The specific processing is the same as step S304 in FIG. 10.

In step S406, the ECC circuit 250 performs error correction decoding process on the read data received from the NAND flash memory 100. When the ECC circuit 250 succeeds in the error correction decoding process (Yes in step S408), this operation proceeds to step S414. On the other hand, when the ECC circuit 250 fails in the error correction decoding process (No in step S408), this operation proceeds to step S410.

In step S410, the read control unit 264 determines whether the current shift index is a shift index to be designated last in the shift table ST. In the example of FIG. 11, the read control unit 264 determines whether the current shift index is the maximum value in the shift table ST. When the current shift index is the maximum value (Yes in step S410), the operation proceeds to step S416. On the other hand, when the current shift index is not the maximum value (No in step S410), the operation proceeds to step S412.

In step S412, the read control unit 264 changes the shift index to a value to be designated next. In the example of FIG. 11, the shift index is incremented by 1. Thereafter, this operation returns to step S404.

In step S414, the read control unit 264 determines that the learning read has been successful, and this operation ends.

In step S416, the read control unit 264 determines that the learning read was unsuccessful, and the operation ends.

In the description of the history value read and the learning read, the read control unit 264 specifies a shift amount from the shift index and transfers the shift amount to the NAND flash memory 100 in the sense operation instruction, but this is not limiting. That is, for example, the read control unit 264 may calculate a voltage value of a voltage applied to the selected word line SelWL from the specified shift amount and transfer the calculated voltage value. In addition, for example, instead of transferring the shift amount for each sense operation instruction, the read control unit 264 may transfer the shift amount when the shift amount used in the sense operation is changed. In addition, for example, the read control unit 264 may instruct the NAND flash memory 100 to change the shift amount in response to a command for giving an instruction to change the shift amount, separate from the sense operation instruction.

The read sequence in this embodiment is an example, and is not limited to the flow described above. That is, for example, before or after the history value read or the learning read, a read method different from these may be executed. In addition, when the selected word line is an edge word line, a read process using a shift value obtained by calibrating the history value may be executed instead of the learning read. In addition, as the learning read, another read method such as tracking reading may be executed instead of the reading using the shift table ST.

### 1.7.2 Write Process

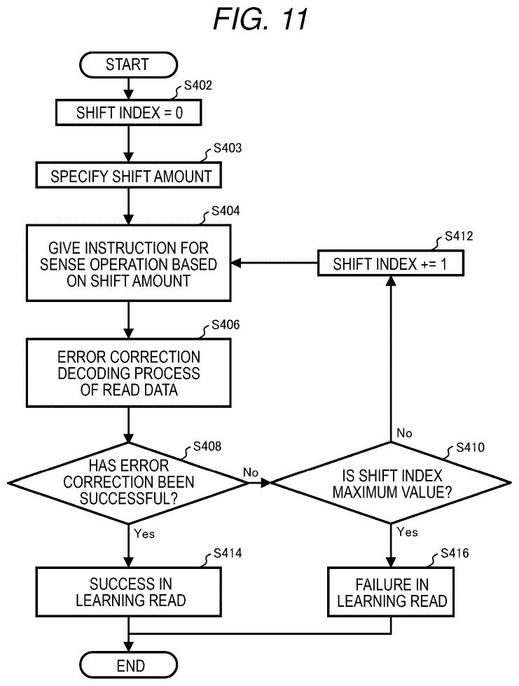

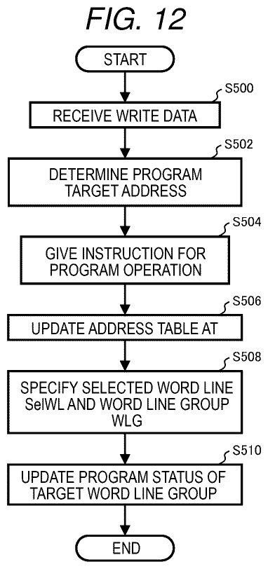

Next, an example of a write process in this embodiment will be described with reference to FIG. 12. FIG. 12 particularly shows a flow of a write process when the memory system 1 uses the history value table HT described with reference to FIG. 7. The memory controller 200 starts the write process by receiving a data write request from the host 300, for example.

In step S500, the memory controller 200 receives write data from the host 300. The received write data is temporarily stored in, for example, the buffer memory 240. The write data undergoes an error correction encoding process by the ECC circuit 250.

In step S502, the memory controller 200 determines a program target address where the write data is to be stored.

In step S504, the memory controller 200 instructs the NAND flash memory 100 to execute a program operation for the write data to the program target address determined in step S502.

In step S506, the memory controller 200 updates the address table AT based on the program target address determined in step S502.

In step S508, the memory controller 200 specifies a word line number of the selected word line SelWL and the corresponding word line group WLG (hereinafter also referred to as a target word line group) based on the program target address determined in step S502. For example, the memory controller 200 specifies a word line group allocation table WT to be referred to from a block address included in the program target address, and specifies a target word line group with reference to the specified word line group allocation table WT.

In step S510, the memory controller 200 updates the program status of the history value table HT for the target word line group specified in step S508. Specifically, the memory controller 200 decrements the number of unprogrammed word lines NupWL of the target word line group by 1, for example, when the selected word line SelWL has been programmed.

The write process ends.

A flow of step S506 and the subsequent steps may be performed individually for each instruction to execute a program operation in step S504, or may be performed collectively for a plurality of instructions to execute a program operation, such as for each write request.

The memory controller 200 may give an instruction to execute a program operation for each piece of data having a page size, or may give an instruction to execute a program operation for each piece of data having a size corresponding to one cell unit CU. Alternatively, the memory controller 200 may give an instruction to execute a program operation for each piece of data having a size corresponding to the total capacity of all memory cells connected to one word line WL. When the memory controller 200 gives an instruction to execute a program operation for each piece of data having a page size or for each piece of data having a size corresponding to one cell unit CU, the memory controller 200 performs the process of step S510, for example, when the program target address is a page or cell unit CU that is to be programmed last in the selected word line SelWL.

In the determination regarding whether to execute history value read in this embodiment, the memory controller 200 refers to the program status of data for the memory cell, but this is not limiting. That is, the memory controller 200 can store, in the history value table HT, other information by which the reliability of the history value read can be estimated instead of or in addition to the program status, and use the information when determining whether to execute the history value read.

### 1.8 Effects

In the memory system according to this embodiment, the program statuses and history values of peripheral memory cells are stored in the main memory so that they can be read out to the same cache line in the cache memory.

Thereby, in the memory system according to this embodiment, it is not necessary to secure a separate cache line or memory area in the main memory for storing information used to determine whether to execute history value read, and thus it is possible to reduce the number of cache lines and memory area required to execute a read process.

Further, in the memory system according to this embodiment, after it is determined to execute history value read, it is not necessary to access the main memory separately to acquire a history value, and thus it is possible to curb an increase in latency.

Although an example in which the memory controller 200 includes one cache memory has been described in this embodiment, this is not limiting. That is, in addition to the cache memory 270, another cache memory may be further provided. In this case, for example, the cache memory 270 is used as a primary cache memory, and the additional cache memory is used as a secondary cache memory. Even in such a configuration, the above-mentioned effects can be obtained by a configuration similar to the configuration described in this embodiment.

### 2. Second Embodiment

Next, a memory system according to a second embodiment will be described. In the first embodiment, the program status of the word lines WL in the word line group WLG is stored in the history value table HT as the program status related to the word line group WLG. In this configuration, as shown in FIG. 9, the memory controller 200 may not be able to determine whether the selected word line SelWL is an edge word line unless the memory controller 200 refers to the program status of the next word line group WLG # (steps S208 to S214 in FIG. 9).

In the second embodiment, the program status related to a word line group WLG in a history value table HT includes the program status of at least one word line WL (hereinafter, also referred to as a reference word line refWL of the word line) that is not included in the word line group WLG.

Hereinafter, description will be given of an example in which the program status related to a word line group WLG in the history value table HT includes the program status of a word line WL that is to be programmed next after the word line group WLG. That is, in the following, a word line WL that is to be programmed next after a certain word line group WLG is a reference word line refWL of the certain word line group WLG. For example, in the configuration of the word line group WLG shown in FIG. 5, a reference word line refWL of the word line group WLG0 is the word line WL3, and a reference word line refWL of the word line group WLG1 is WL6.

Hereinafter, description of the same configurations and operations as those in the first embodiment may be omitted.

### 2.1 History Value Table

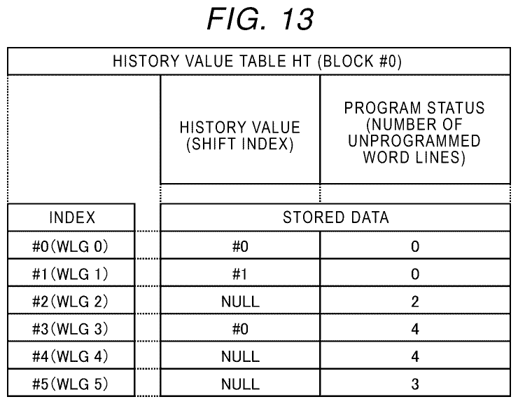

FIG. 13 is a diagram showing an example of a history value table HT used in the memory system according to this embodiment. In particular, FIG. 13 shows an example of the history value table HT in the configuration of the word line group WLG shown in FIGS. 4 and 5.

In this embodiment, a shift index is stored as a history value in each entry of the history value table HT, and the number of unprogrammed word lines WL, among word lines WL in a word line group WLG and a reference word line refWL of the word line group WLG, is stored as the program status related to the word line group WLG. For example, in FIG. 13, the number of unprogrammed word lines WL, among word lines WL0 to WL2 in a word line group WLG0 and a word line WL3 which is a reference word line refWL, is stored in an entry corresponding to the word line group WLG0. Similarly, the number of unprogrammed word lines WL among word lines WL3 to WL6 is stored in an entry corresponding to a word line group WLG1. Hereinafter, in this embodiment, the number of unprogrammed word lines WL among word lines WL in a certain word line group WLG and a reference word line refWL of the certain word line group WLG will be referred to as the number of unprogrammed word lines NupWL for the certain word line group WLG.

The correspondence between the word line group WLG and the reference word line refWL is not limited to the example described in this embodiment, and can be set freely and selectively from the viewpoint of the characteristics of the word lines WL in the word line group WLG. In addition, there may be a word line group WLG that does not have a reference word line refWL.

In this embodiment, the number of unprogrammed word lines NupWL can take an integer value of equal to or greater than 0 and equal to or less than the quantity in word line group Nwl+1. When the number of unprogrammed word lines NupWL is 0, it indicates that all of the word lines WL in the word line group WLG have been programmed, and that the reference word line refWL of the word line group WLG has been programmed. In addition, when the number of unprogrammed word lines NupWL is equal to the quantity in word line group Nwl+1, it indicates that none of the word lines WL in the word line group WLG and the reference word line refWL of the word line group WLG have been programmed. In addition, when the number of unprogrammed word lines NupWL is 1, it indicates that all of the word lines WL in the word line group WLG have been programmed, but the reference word line refWL of the word line group WLG has not been programmed.

In this embodiment, the word line group WLG that is to be programmed last in a block BLK does not have a reference word line refWL. That is, the number of unprogrammed word lines NupWL corresponding to the word line group WLG that is to be programmed last in the block BLK indicates the program status of the word lines WL in the word line group WLG. In this embodiment, like all other word lines groups WLG, when the word line group WLG has not been programmed, (the number of word lines WL that have not been programmed among the word lines WL in the word line group WLG)+1 is stored as the number of unprogrammed word lines NupWL. On the other hand, unlike other word line groups WLG, when the word line group WLG has been programmed, 0 is stored as the number of unprogrammed word lines NupWL. That is, in this embodiment, the number of unprogrammed word lines NupWL of the word line group WLG that is to be programmed last in a block BLK can take integer values of 0 to the quantity in word line group Nwl+1, except for 1. In FIG. 13, for example, in an entry corresponding to a word line group WLG5, when the word line group WLG5 has not been programmed, (the number of unprogrammed word lines WL among the word lines WL14 to WL15)+1 is stored as the number of unprogrammed word lines NupWL, and when the word line group WLG5 has been programmed, 0 is stored.

When the block BLK has been erased, the number of all unprogrammed word lines NupWL stored in the history value table HT corresponding to the block BLK is equal to the quantity in corresponding word line groups Nwl+1. That is, when an erase operation is performed on the block BLK, the program status stored in the history value table HT corresponding to the block BLK is initialized to the quantity in word line group Nwl+1. These initialization processes are performed, for example, by an erase control unit 266.

The example in FIG. 13 corresponds to a state in which the word lines WL0 to WL6 have been programmed in the configuration of the word line group WLG as shown in FIGS. 4 and 5. For the word line groups WLG0 to WLG1, the number of unprogrammed word lines NupWL is 0, which indicates that the word lines WL in the word line groups WLG0 to WLG1 and reference word lines refWL (WL0 to WL6) have been all programmed. For the word line group WLG2, the number of unprogrammed word lines NupWL is 2, which is 1 smaller than the initial value of 3. This indicates that, among the word lines WL in the word line group WLG2 and reference word lines refWL (WL6 to WL8), only WL6 which is to be programmed first has been programmed. In addition, for the word line groups WLG3 to WLG4, the number of unprogrammed word lines NupWL is equal to the quantity in word line group Nwl+1, which indicates that none of the word lines WL in the word line groups WLG3 to WLG4 and reference word lines refWL (WL8 to WL14) have been programmed. In addition, for the word line group WLG5, the number of unprogrammed word lines NupWL is equal to the quantity in word line groups Nwl+1, which indicates that none of the word lines WL (WL14 to WL15) in the word line group WLG5 have been programmed.

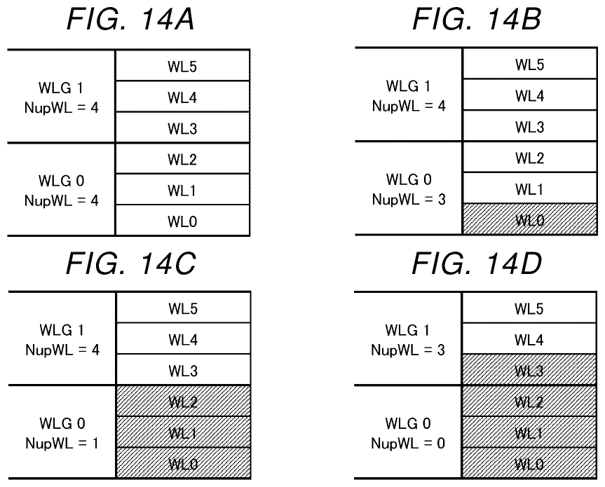

Here, referring to FIGS. 14A to 14D, an example of a transition of the number of unprogrammed word lines NupWL in the history value table HT is described. FIGS. 14A to 14D show an example of a transition of the number of unprogrammed word lines NupWL of the word line groups WLG0 and WLG1 in the configuration of the word line group WLG as shown in FIGS. 4 and 5. In a table shown in FIGS. 14A to 14D, each square corresponds to one word line WL.

In FIGS. 14A to 14D, a blank square indicates that the corresponding word line WL has not been programmed, and a hatched square indicates that the corresponding word line WL has been programmed. As described above, for simplicity, in this embodiment, it is assumed that word lines have been programmed in a block BLK in ascending order of word line numbers. In FIGS. 14A to 14D, the word line WL located at the top among the hatched word lines WL is an edge word line.

As shown in FIG. 14A, when the block BLK has been erased, the number of unprogrammed word lines NupWL corresponding to the word line groups WLG0 and WLG1 is an initial value of 4. Specifically, for example, the number of unprogrammed word lines NupWL corresponding to the word line group WLG0 is 4, which is the total number of word lines WL0 to WL2 and a word line WL3.

Next, as shown in FIG. 14B, in a state where the word line WL0 has been programmed, the number of unprogrammed word lines NupWL in the word line group WLG0 is 3 (=4−1). Since the word line WL0 is an edge word line, execution of history value read is skipped in a read sequence in which the word line WL0 is set as a selected word line SelWL.

Next, as shown in FIG. 14C, in a state where the word lines WL1 and WL2 has been further programmed, the number of unprogrammed word lines NupWL in the word line group WLG0 is 1(=4−3). In this state, since the word line WL2 is an edge word line, execution of history value read is skipped in a read sequence in which the word line WL2 is set as a selected word line SelWL. On the other hand, in a read sequence in which the word line WL0 or WL1 is set as a selected word line SelWL, history value read is executed when there is a history value corresponding to the word line group WLG0. In the state shown in FIG. 14C, the word line group WLG0 has already been programmed.

Furthermore, as shown in FIG. 14D, in a state where the word line WL3 has also been programmed, the number of unprogrammed word lines NupWL in the word line group WLG0 is 0(=4−4). At this time, none of the word lines WL (WL0 to WL2) in the word line group WLG0 are edge word lines. In addition, the number of unprogrammed word lines NupWL in the word line group WLG1 is 3(=4−1).

As in the first embodiment, each entry in the history value table HT corresponds to one aligned area.

Further, in the history value table HT, for example, the number of programmed word lines WL, among the word lines WL in the word line group WLG and a reference word lines refWL, may be stored as a program status. Alternatively, the number of the word line WL that is to be programmed last among the word lines WL, or information listing whether the word lines WL have been programmed may be stored as a program status.

As described above, in the history value table HT of this embodiment, a program status (the number of unprogrammed word lines NupWL) stored corresponding to the word line group WLG includes the program status of a word line WL (reference word line refWL) that is to be programmed next after the word line group WLG. Thus, even when the memory controller 200 performs edge word line determination for a word line WL to be programmed last in the word line group WLG, it is not necessary to refer to the program status of a next word line group WLG # of a target word line group, and an increase in the number of accesses to the main memory 230 can be curbed.

### 2.2 Operation

Next, the operation of the memory system according to this embodiment will be described. An example of a read sequence in this embodiment is the same as that in the first embodiment (described with reference to FIG. 8), and thus the description thereof will be omitted. Examples of flows of history value read and learning read in this embodiment are the same as those in the first embodiment (described with reference to FIGS. 10 and 11, respectively), and thus the description thereof will be omitted.

### 2.2.1 Edge Word Line Determination

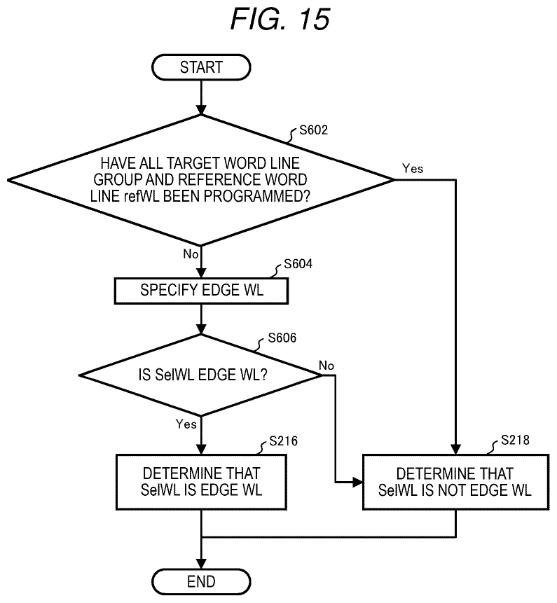

First, a specific example of a flow of edge word line determination in this embodiment will be described with reference to FIG. 15. FIG. 15 shows a flow of edge word line determination, particularly when the history value table HT described with reference to FIG. 13 is used. The following steps S602 to S606, step S216, and step S218 are a flow equivalent to step S200 in FIG. 8.

When the edge word line determination starts, the read control unit 264 determines in step S602 whether a target word line group and a reference word line refWL of the target word line group have been all programmed. Specifically, for example, the read control unit 264 determines whether the acquired number of unprogrammed word lines NupWL is 0. When the acquired number of unprogrammed word lines NupWL is 0, that is, when the target word line group and the reference word line refWL of the target word line group have been all programmed (Yes in step S602), this operation proceeds to step S218. On the other hand, when the acquired number of unprogrammed word lines NupWL is not 0, that is, when any of the target word line group and the reference word line refWL of the target word line group has not been programmed (No in step S602), this operation proceeds to step S604.

In step S604, the read control unit 264 specifies an edge word line in a block BLK to be sensed. Specifically, for example, the read control unit 264 specifies a word line number of the edge word line as Edge WL Number=WLGmax−NupWL+1. Here, WLGmax is the number of the end word line of the target word line group.

In step S606, the read control unit 264 determines whether the selected word line SelWL is the edge word line specified in step S604. Specifically, for example, the read control unit 264 determines whether the relation of SelWL Number=Edge WL Number is satisfied. When the relation of SelWL Number=Edge WL Number is satisfied, that is, when the selected word line SelWL is the edge word line specified in step S604 (Yes in step S606), this operation proceeds to step S216. On the other hand, when the relation of SelWL Number=Edge WL Number is not satisfied, that is, when the selected word line SelWL is not the edge word line specified in step S604 (No in step S606), this operation proceeds to step S218.

In step S216, the read control unit 264 determines that the selected word line SelWL is an edge word line, and this operation ends.

In step S218, the read control unit 264 determines that the selected word line SelWL is not an edge word line, and this operation ends.

In step S602, the read control unit 264 performs determination by regarding the number of unprogrammed word lines NupWL as a bool value. At this time, when the number of unprogrammed word lines NupWL indicates False, the read control unit 264 determines step S602 to be Yes, and when the number of unprogrammed word lines NupWL indicates True, the read control unit 264 determines step S602 to be No. The determination performed by regarding the value as a bool value is faster than determination performed by regarding the value as a numerical value, and latency in the edge word line determination can be reduced.

### 2.2.2 Write Process

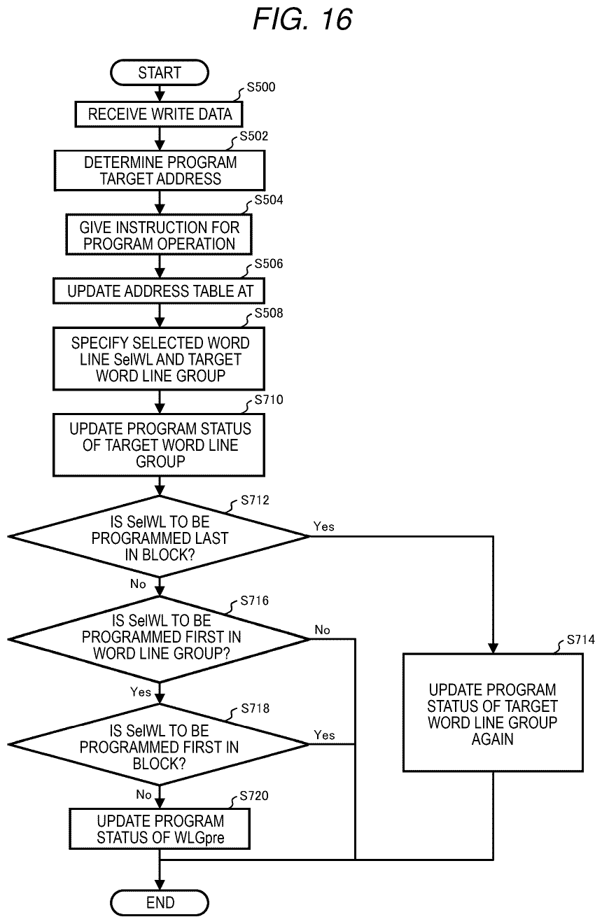

Next, an example of a write process in this embodiment will be described with reference to FIG. 16. FIG. 16 particularly shows a flow of a write process when the memory system 1 uses the history value table HT described with reference to FIG. 13. In FIG. 16, the same processes as those described in the first embodiment are performed in steps having the same numbers as the step numbers in the first embodiment (FIG. 12). Description of the steps (steps S500 to S508) will be omitted.

In step S710, the memory controller 200 updates the program status of the history value table HT for the target word line group specified in step S508. Specifically, the memory controller 200 decrements the number of unprogrammed word lines NupWL of the target word line group by 1, for example, when the selected word line SelWL has been programmed.

In step S712, the memory controller 200 determines whether the selected word line SelWL is a word line WL that is to be programmed last in the block BLK. Specifically, for example, the memory controller 200 determines whether the relation of SelWL Number=WLmax is satisfied. Here, WLmax is the word line number with the largest value among the word line numbers of the word lines WL in the block BLK. When the relation of SelWL Number=WLmax is satisfied, that is, when the selected word line SelWL is the word line WL to be programmed last in the block BLK (Yes in step S712), this operation proceeds to step S714. On the other hand, when the relation of SelWL Number=WLmax is not satisfied, that is, when the selected word line SelWL is not the word line WL to be programmed last in the block BLK (No in step S712), this operation proceeds to step S716.

In step S714, the memory controller 200 updates the program status of the history value table HT again for the target word line group. Specifically, the memory controller 200 sets the number of unprogrammed word lines NupWL of the target word line group to 0. By this step, for the word line group WLG that is to be programmed last in the block BLK, the number of unprogrammed word lines NupWL is set to 0 when all of the word lines WL in the word line group WLG have been programmed.

In step S716, the memory controller 200 determines whether the selected word line SelWL is a word line WL to be programmed first in the target word line group. Specifically, for example, the read control unit 264 determines whether the relation of SelWL Number=WLGmin is satisfied. Here, WLGmin is the word line number of a start word line of the target word line group. When the relation of SelWL Number=WLGmin is satisfied, that is, when the selected word line SelWL is a word line WL to be programmed first in the target word line group (Yes in step S716), this operation proceeds to step S718. On the other hand, when the relation of SelWL Number=WLGmin is not satisfied, that is, when the selected word line SelWL is not a word line WL to be programmed first in the target word line group (No in step S716), this operation ends.

In step S718, the memory controller 200 determines whether the selected word line SelWL is a word line WL that is to be programmed first in the block BLK. Specifically, for example, the memory controller 200 determines whether the relation of SelWL Number=WLmin is satisfied. Here, WLmin is a word line number with the smallest value among the word line numbers of the word lines WL in the block BLK. When the relation of SelWL Number=WLmin is satisfied, that is, when the selected word line SelWL is a word line WL to be programmed first in the block BLK (Yes in step S718), this operation ends. On the other hand, when the relation of SelWL Number=WLmin is not satisfied, that is, when the selected word line SelWL is not a word line WL to be programmed first in the block BLK (No in step S718), this operation proceeds to step S720.

In step S720, the memory controller 200 updates the number of unprogrammed word lines NupWL in a previous word line group WLGpre of the target word line group. The previous word line group WLGpre of the target word line group is a word line group WLG that has the word line WL, which is to be programmed first in the target word line group, as a reference word line refWL. Specifically, for example, when the target word line group is a word line group WLGn (n is an integer equal to or greater than 1), the memory controller 200 decrements the number of unprogrammed word lines NupWL of a word line group WLG(n−1) by 1 in step S720. By this step, the program status of the reference word line refWL of the word line group WLG is reflected in the program status related to the word line group WLG stored in the history value table HT. Then, the write process ends.

In step S712, the memory controller 200 determines whether the selected word line SelWL is a word line WL that is to be programmed last in the target word line group, but this is not limiting. That is, for example, the memory controller 200 may determine whether the target word line group is a word line group WLG that is to be programmed last in the block BLK, and whether the selected word line SelWL is a word line WL that is to be programmed last in the target word line group.

Further, in step S716, the memory controller 200 determines whether the selected word line SelWL is a word line WL that is to be programmed first in the target word line group, but this is not limiting. That is, for example, instead of the above determination, the memory controller 200 may determine whether the target word line group is a word line group WLG that is to be programmed first in the block BLK. In this case, for example, the memory controller 200 determines whether the target word line group is WLG0.

Further, in the write process, when the selected word line SelWL is a word line WL that is to be programmed last in the block BLK (Yes in step S712), the memory controller 200 updates the program status of the target word line group again, but this is not limiting. That is, for example, instead of incorporating the above steps into the write process, a step of determining whether a block BLK to be sensed has been programmed may be incorporated into edge word line determination. In this case, for a word line group WLG that is to be programmed last in the block BLK, when the word line group WLG has been programmed, 1 is stored as the number of unprogrammed word lines NupWL.

### 2.3 Effects

In the memory system according to this embodiment, the program status of the word line group WLG in the history value table HT includes the program status of at least one word line WL (reference word line refWL) that is not included in the word line group WLG. Specifically, in this embodiment, for example, the program status of a word line WL that is to be programmed next after the word line group WLG is included.

Thereby, in the memory system according to this embodiment, when determining whether to execute history value read, the memory controller does not need to refer to program statuses stored in a plurality of different entries in a history value table, and thus it is possible to curb an increase in latency due to access to the main memory.

### 3. Third Embodiment

Next, a memory system according to a third embodiment will be described. In the first and second embodiments, the memory controller 200 stores program statuses in units of memory cells connected to the word lines WL, and uses the program statuses to determine whether to execute history value read. In the third embodiment, a memory controller 200 stores program statuses in units smaller than the word lines WL, and uses the program statuses to determine whether to execute history value read. In the following, particularly, a case where the memory controller 200 stores the program statuses in units of cell units CU and uses the program statuses to determine whether to execute history value read will be described in comparison with the second embodiment. In the following, the description of the same configurations and operations as those in the second embodiment may be omitted.

### 3.1 History Value Table

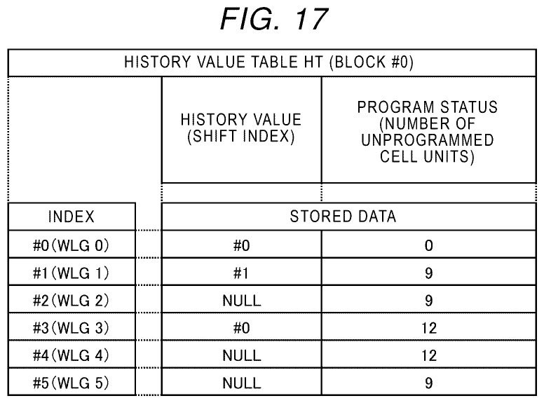

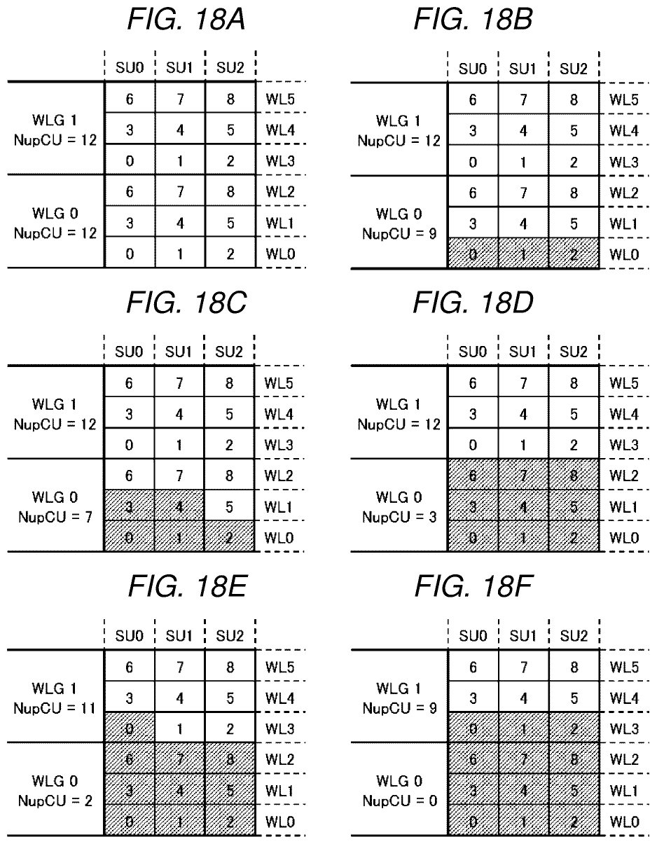

First, a history value table HT according to the third embodiment will be described with reference to FIGS. 17 and 18. FIG. 17 is a diagram showing an example of the history value table HT used in the memory system according to this embodiment. In particular, FIG. 17 shows an example of the history value table HT in the configuration of the word line group WLG shown in FIGS. 4 and 5.

In this embodiment, a shift index is stored as a history value in each entry of the history value table HT, and the number of cell units CU that have not programmed (hereinafter also referred to as the number of unprogrammed cell units NupCU), among cell units CU connected to the word line group WLG and a reference word line refWL of the word line group WLG, is stored as the program status related to the word line group WLG. In this description, “the cell unit CU has been programmed” means that all memory cells corresponding to the cell unit CU have been programmed.

In this embodiment, the number of unprogrammed cell units NupCU can take an integer value of equal to or greater than 0 and equal to or less than (the quantity in word line groups Nwl+1)×the number of string units Nsu. The number of string units Nsu is the number of string units SU included in a block BLK. The number of string units Nsu is equal to the number of cell units CU connected to one word line WL. For example, when a program operation is performed on a certain word line group WLG and any of cell units CU connected to a reference word line refWL of the certain word line group WLG, the memory controller 200 decrements the number of unprogrammed cell units NupCU corresponding to the certain word line group WLG by 1.

When the block BLK has been erased, the number of all unprogrammed cell units NupCU stored in a history value table HT corresponding to the block BLK is equal to the corresponding (quantity in word line group Nwl+1)×the number of string units Nsu. That is, when an erase operation is performed on the block BLK, the program status stored in the history value table HT corresponding to the block BLK is initialized to (Nwl+1)×Nsu. Specifically, for example, in the configuration of the word line group WLG shown in FIGS. 4 and 5, the number of unprogrammed cell units NupCU in the word line group WLG0 is initialized to 12(=(3+1)×3). In addition, the number of unprogrammed cell units NupCU in the word line group WLG2 is initialized to 9(=(2+1)×3). These initialization processes are executed, for example, by an erase control unit 266.

Here, an example of a transition of the number of unprogrammed cell units NupCU in the history value table HT is described with reference to FIGS. 18A to 18F. FIGS. 18A to 18F show an example of a transition of the number of unprogrammed cell units NupCU in the word line groups WLG0 and WLG1 in the configuration of the word line group WLG shown in FIGS. 4 and 5. In a table shown in FIGS. 18A to 18F, each square corresponds to one cell unit CU, a column indicates a string unit SU corresponding to each cell unit CU, and a row indicates a word line WL corresponding to each cell unit CU.

In addition, as shown in each square in FIGS. 18A to 18F, the memory controller 200 assigns a cell unit number to each cell unit CU in the word line group WLG. Specifically, the memory controller 200 assigns a cell unit number (Nsu×(i−WLGmin)+j) to a cell unit CU that corresponds to a word line WLi and a string unit SUj. Here, WLGmin is the word line number of a start word line of the corresponding word line group WLG. For example, a cell unit CU corresponding to a word line WL1 and a string unit SU2 is assigned cell unit number 5(=3×(1−0)+2). Similarly, a cell unit CU corresponding to a word line WL4 and a string unit SU1 is assigned cell unit number 4(=3×(4−3)+1). Hereinafter, a cell unit CU connected to a word line group WLGn and assigned cell unit number m may be simply referred to as CU(n, m).

The memory controller 200 may store cell unit numbers corresponding to cell units CU in the word line group WLG as a table associated with word line numbers. Alternatively, the memory controller 200 may calculate the cell unit numbers from the corresponding word line numbers and string unit numbers using the above formula or other formulas.

In FIGS. 18A to 18F, a blank square indicates that the corresponding cell unit CU has not been programmed, and a hatched square indicates that the corresponding cell unit CU has been programmed. In this embodiment, it is assumed that cell units CU connected to the same word line WL are programmed in ascending order of the string unit numbers of the corresponding string units SU. That is, in the block BLK of this embodiment, programming is performed in ascending order of cell unit numbers.

Hereinafter, a cell unit CU that is programmed last in the string unit SU may be referred to as an edge cell unit or an edge CU. Similarly to the edge word line, the memory cells around the edge cell unit include at least memory cells that have not been programmed. Hereinafter, in this embodiment, the read control unit 264 determines whether a cell unit CU (hereinafter also referred to as a sense target cell unit) corresponding to a sense target address is an edge cell unit when determining whether to execute history value read. When the sense target cell unit is an edge cell unit, the read control unit 264 skips the execution of history value read in the read sequence. In FIGS. 18A to 18F, among the hatched cell units CU, the cell unit CU located at the top of each column is an edge cell unit.

As shown in FIG. 18A, when the block BLK has been erased, the number of unprogrammed cell units NupCU corresponding to the word line groups WLG0 and WLG1 is an initial value of 12. Specifically, for example, the number of unprogrammed cell units NupCU corresponding to the word line group WLG0 is 12, which is the sum of the number of cell units CU(0,0) to CU(0,8) connected to the word lines WL0 to WL2, which is 9, and the number of cell units CU(1,0) to CU(1,2) connected to the word line WL3, which is 3.

Next, as shown in FIG. 18B, in a state where the cell units CU(0,0) to CU(0,2) have been programmed, the number of unprogrammed cell units NupCU in the word line group WLG0 is 9(=12−3). The cell units CU(0,0) to CU(0,2) are edge cell units, and thus the execution of history value read is skipped in a read sequence in which these cell units CU are sense target cell units.

Next, as shown in FIG. 18C, in a state where the cell units CU(0,3) and CU(0,4) have been further programmed, the number of unprogrammed cell units NupCU in the word line group WLG0 is 7(=12−5). In this state, the cell units CU(0,2) to CU(0,4) are edge cell units, and thus the execution of history value read is skipped in a read sequence in which these cell units CU are sense target cell units. On the other hand, the cell units CU(0,0) to CU(0,1) are not edge cell units, and thus history value read is executed when there is a history value corresponding to the word line group WLG0 in a read sequence in which these cell units CU are sense target cell units.

Furthermore, as shown in FIG. 18D, in a state where the cell units CU(0,5) to CU(0,8) have been further programmed, the number of unprogrammed cell units NupCU in the word line group WLG0 is 3(=12−9). In the state shown in FIG. 18D, all cell units CU connected to the word line group WLG0 have been programmed.

Furthermore, as shown in FIG. 18E, in a state where the cell unit CU(1,0) has been further programmed, the number of unprogrammed cell units NupCU in the word line group WLG0 is 2(=12−10). In addition, the number of unprogrammed cell units NupCU in the word line group WLG1 is 11(=12−1).

In addition, as shown in FIG. 18F, in a state where the cell units CU(1,1) and CU(1,2) have been further programmed, the number of unprogrammed cell units NupCU in the word line group WLG0 is 0(=12−12). At this time, none of the cell units CU connected to the word line group WLG0 are edge cell units. In addition, the number of unprogrammed cell units NupCU in the word line group WLG1 is 9(=12−3).

As described above, in this embodiment, the number of unprogrammed cell units NupCU corresponding to the word line group WLG can take an integer value of equal to or greater than 0 and equal to or less than (Nwl+1)×Nsu, depending on the program status of the block BLK. When the number of unprogrammed cell units NupCU is 0, it indicates that all of the cell units CU connected to the word line group WLG have been programmed, and that all cell units CU connected to a reference word line refWL of the word line group WLG have been programmed. In addition, when the number of unprogrammed cell units NupCU is equal to (Nwl+1)×Nsu, it indicates that none of the cell units CU connected to the word line group WLG or the reference word line refWL of the word line group WLG have been programmed. In addition, when the number of unprogrammed cell units NupCU is equal to the number of string units Nsu, it indicates that all of the cell units CU connected to the word line group WLG have been programmed, but none of the cell units CU connected to the reference word line refWL of the word line group WLG have been programmed.

For the word line group WLG that is to be programmed last in the block BLK, the number of unprogrammed cell units NupCU indicates the program status of the cell units CU connected to the word line group WLG. In this embodiment, like all other word line groups WLG, when any of the cell units CU connected to the word line group WLG has not been programmed, (the number of cell units CU that have not been programmed among the cell units CU connected to the word line group WLG)+Nsu is stored as the number of unprogrammed cell units NupCU. On the other hand, unlike other word line groups WLG, when all of the cell units CU connected to the word line group WLG have been programmed, 0 is stored as the number of unprogrammed cell units NupCU. That is, in this embodiment, the number of unprogrammed cell units NupCU of the word line group WLG that is to be programmed last in the block BLK can take integer values of 0 and equal to or greater than Nsu+1 and equal to or less than (Nwl+1)×Nsu.

Referring back to FIG. 17, an example of a history value table HT will be described. The example in FIG. 17 corresponds to the program status shown in FIG. 18F. For the word line group WLG0, the number of unprogrammed cell units NupCU is 0, which indicates that all of the cell units CU connected to the word line group WLG0 and the reference word lines refWL (WL0 to WL3) of the word line group WLG0 have been programmed. In addition, for the word line group WLG1, the number of unprogrammed word lines NupWL is 9, which is 3 smaller than the initial value of 12. This indicates that, among the cell units CU connected to the word lines WL in the word line group WLG1 and reference word lines refWL (WL3 to WL6), the first to third cell units CU(1,0) to CU(1,2) to be programmed have been programmed. In addition, for the word line group WLG2 to WLG4, the number of unprogrammed cell units NupCU is equal to the initial value of (Nwl+1)×Nsu, which indicates that none of the cell units CU connected to the word line groups WLG2 to WLG4 and their reference word lines refWL (WL6 to WL14) have been programmed. In addition, for the word line group WLG5, the number of unprogrammed cell units NupCU is equal to the initial value of (Nwl+1)×Nsu, which indicates that none of the cell units CU connected to the word lines (WL14 to WL15) in the word line group WLG5 have been programmed.

As in the second embodiment, each entry in the history value table HT corresponds to one aligned area.

Further, in the history value table HT shown in FIG. 17, the number of unprogrammed cell units NupCU is stored as a program status, but this is not limiting. For example, the number of programmed cell units CU among the cell units CU connected to the word line group WLG and the reference word line refWL of the word line group WLG may be stored as a program status. Alternatively, the cell unit number of the cell unit CU that has been programmed last among the cell units CU, or information listing whether each cell unit CU has been programmed may be stored as a program status.

Further, in the history value table HT shown in FIG. 17, one history value is stored for one word line group WLG, but this is not limiting. That is, for example, the number of history values corresponding to the number of string units Nsu may be stored for one word line group WLG. In this case, the memory controller 200 can select a history value for each string unit including cell units CU and use it for history value read.

### 3.2 Operation

Next, the operation of the memory system according to this embodiment will be described. Examples of flows of history value read and learning read in this embodiment are the same as those in the first embodiment (described with reference to FIGS. 10 and 11, respectively), and thus the description thereof will be omitted.

### 3.2.1 Read Sequence

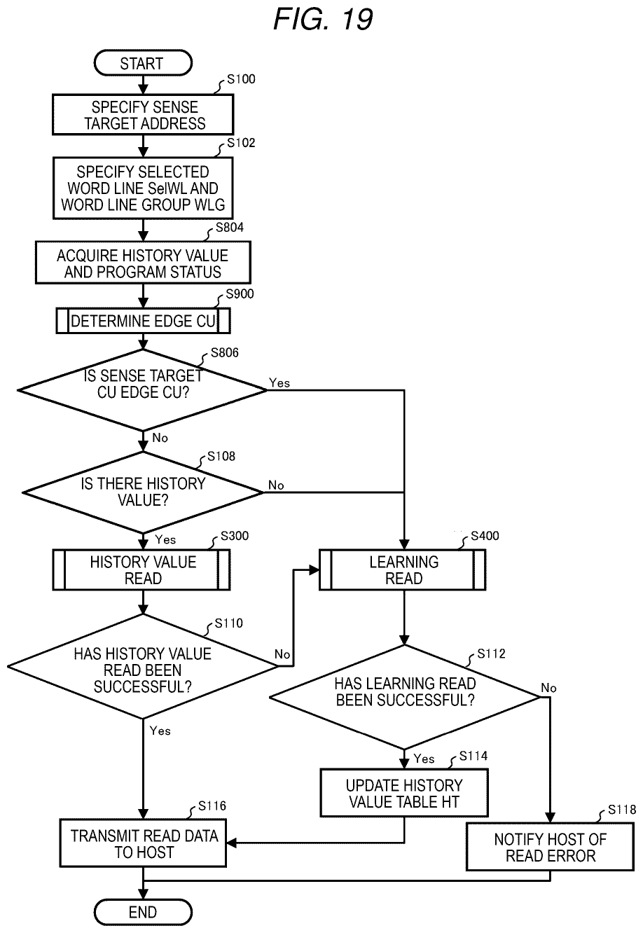

First, an example of a read sequence in this embodiment will be described with reference to FIG. 19. In FIG. 19, the same processes as those described in the first embodiment are performed in steps having the same numbers as the step numbers in the first embodiment (FIG. 8). Description of the steps will be omitted.

In step S804, the memory controller 200 acquires the history value and program status of the word line group WLG specified in step S102 with reference to the history value table HT. Specifically, in this embodiment, the memory controller 200 acquires a shift index as the history value and acquires the number of unprogrammed cell units NupCU as the program status. The memory controller 200 specifies a history value table HT to be referred to, for example, from a block address included in a sense target address.

In step S900, the memory controller 200 determines whether the sense target cell unit is an edge cell unit (hereinafter, also referred to as edge cell unit determination) based on the number of unprogrammed cell units NupCU acquired in step S804. Details of the edge cell unit determination will be described later. As a result of the edge cell unit determination, when it is determined that the sense target cell unit is an edge cell unit (Yes in step S806), this operation proceeds to step S400. On the other hand, as a result of the edge cell unit determination, when it is determined that the sense target cell unit is not an edge cell unit (No in step S806), this operation proceeds to step S108.

### 3.2.2 Edge Cell Unit Determination

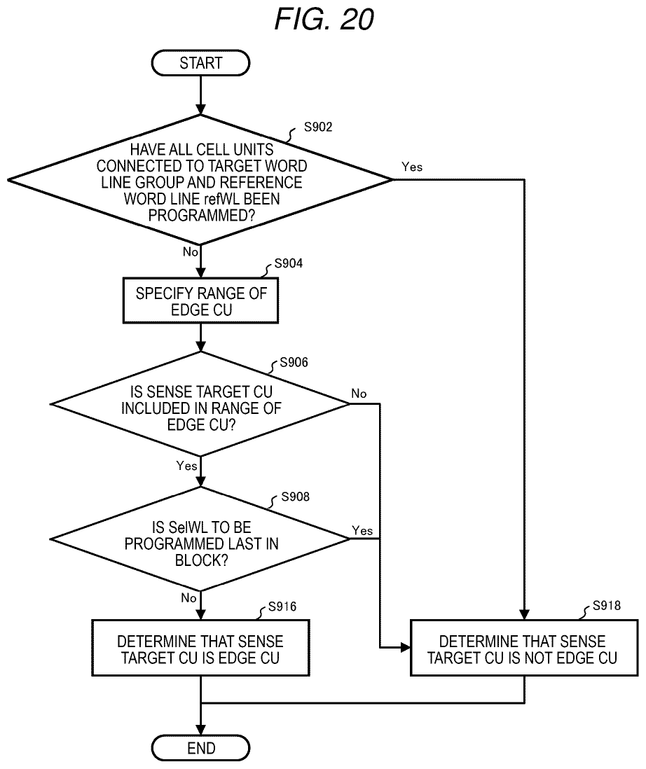

Next, a specific example of a flow of edge cell unit determination in this embodiment will be described with reference to FIG. 20. FIG. 20 shows a flow of edge cell unit determination, particularly when the history value table HT described with reference to FIG. 17 is used. The following steps S902 to S918 are a flow equivalent to step S900 in FIG. 19.

When the edge cell unit determination starts, the read control unit 264 determines in step S902 whether all cell units CU connected to a target word line group and a reference word line refWL of the target word line group have been programmed. Specifically, for example, the read control unit 264 determines whether the acquired number of unprogrammed cell units NupCU is 0. When the acquired number of unprogrammed cell units NupCU is 0, that is, when all of the cell units CU connected to the target word line group and reference word line refWL of the target word line group have been programmed (Yes in step S902), this operation proceeds to step S918. On the other hand, when the acquired number of unprogrammed cell units NupCU is not 0, that is, when any of the cell units CU connected to the target word line group and reference word line refWL of the target word line group has not been programmed (No in step S902), this operation proceeds to step S904.

In step S904, the read control unit 264 specifies the range of the edge cell units in the target word line group. Specifically, for example, the read control unit 264 specifies the minimum value of the cell unit numbers of the edge cell units as edgeCUmin=Nwl×Nsu NupCU. In addition, for example, the read control unit 264 specifies the maximum value of the cell unit numbers of the edge cell units as edgeCUmax=edgeCUmin+Nsu−1. Nwl×Nsu is equal to the number of cell units CU included in the target word line group. The memory controller 200 may store this value for each word line group WLG, or may calculate it in step S904. The memory controller 200 may also calculate the maximum value of the cell unit numbers of the edge cell units as edgeCUmax=(Nwl+1)×Nsu−NupCU−1.

In step S906, the read control unit 264 determines whether the sense target cell unit is included in the edge cell unit range specified in step S904. Specifically, for example, the read control unit 264 determines whether the relation of edgeCUmin≤sense target cell unit number≤edgeCUmax is satisfied. When the relation of edgeCUmin≤sense target cell unit number≤edgeCUmax is satisfied, that is, when the sense target cell unit is included in the edge cell unit range specified in step S904 (Yes in step S906), this operation proceeds to step S908. On the other hand, when the relation of edgeCUmin≤sense target cell unit number≤edgeCUmax is not satisfied, that is, when the sense target cell unit is not included in the edge cell unit range specified in step S904 (No in step S906), this operation proceeds to step S918.

In step S908, the read control unit 264 determines whether the selected word line SelWL is a word line WL that is to be programmed last in the block BLK. Specifically, for example, the read control unit 264 determines whether the relation of SelWL Number=WLmax is satisfied. Here, WLmax is the word line number with the largest value among the word line numbers of the word lines WL in the block BLK. When the relation of SelWL Number=WLmax is satisfied, that is, the selected word line SelWL is a word line WL that is to be programmed last in the block BLK (Yes in step S908), this operation proceeds to step S918. On the other hand, when the relation of SelWL Number=WLmax is not satisfied, that is, when the selected word line SelWL is not a word line WL to be programmed last in the block BLK (No in step S908), this operation proceeds to step S916. This step may be performed only when the target word line group is a word line group WLG that is to be programmed last in the block BLK.

In step S916, the read control unit 264 determines that the sense target cell unit is an edge cell unit, and this operation ends.

In step S918, the read control unit 264 determines that the sense target cell unit is not an edge cell unit, and this operation ends.

### 3.2.3 Write Process

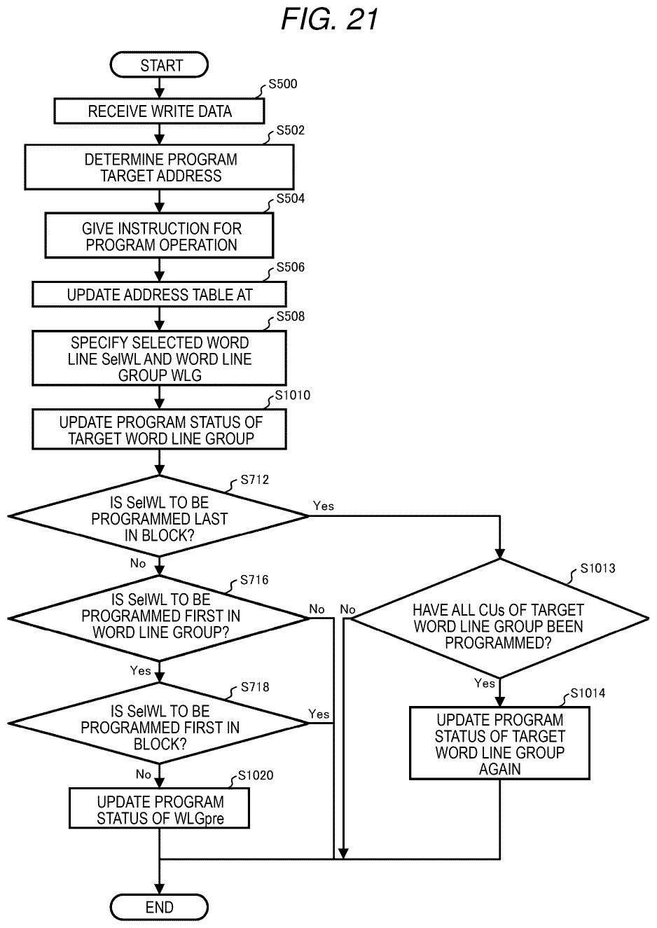

Next, an example of a write process in this embodiment will be described with reference to FIG. 21. FIG. 21 particularly shows a flow of a write process when the memory system 1 uses the history value table HT described with reference to FIG. 17. In FIG. 21, the same processes as the step numbers described in these embodiments are performed in steps having the same numbers as those in the first embodiment (FIG. 12). Description of the steps (steps S500 to S508) will be omitted. Further, in FIG. 21, detailed descriptions of steps having the same numbers as the step numbers in the second embodiment (FIG. 16) may be omitted.

In step S1010, the memory controller 200 updates the program status of the history value table HT for the target word line group specified in step S508. Specifically, the memory controller 200 decrements the number of unprogrammed cell units NupCU of the target word line group by 1, for example, when the cell unit CU to be programmed has been programmed.

In step S712, the memory controller 200 determines whether the selected word line SelWL is a word line WL to be programmed last in the block BLK. When the selected word line SelWL is a word line WL to be programmed last in the block BLK (Yes in step S712), this operation proceeds to step S1013. On the other hand, when the selected word line SelWL is not a word line WL to be programmed last in the block BLK (No in step S712), this operation proceeds to step S716.

In step S1013, the memory controller 200 determines whether all of the cell units CU of the target word line group have been programmed. Specifically, for example, the memory controller 200 determines whether the relation of the number of unprogrammed cell units NupCU≤Nsu is satisfied. However, the number of unprogrammed cell units NupCU is the value after being updated in step S1010. When the relation of NupCU≤Nsu is satisfied, that is, when all of the cell units CU of the target word line group have been programmed (Yes in step S1013), this operation proceeds to step S1014. On the other hand, when the relation of NupCU≤Nsu is not satisfied, that is, when any of the cell units CU of the target word line group has not been programmed (No in step S1013), this operation ends.

In step S1014, the memory controller 200 updates the program status of the history value table HT again for the target word line group. Specifically, the memory controller 200 sets the number of unprogrammed cell units NupCU of the target word line group to 0. By this step, for the word line group WLG that is to be programmed last in block BLK, when all of the cell units CU in the word line group WLG have been programmed, the number of unprogrammed cell units NupCU is 0.

In step S716, the memory controller 200 determines whether the selected word line SelWL is a word line WL to be programmed first in the target word line group. When the selected word line SelWL is a word line WL to be programmed first in the target word line group (Yes in step S716), this operation proceeds to step S718. On the other hand, when the selected word line SelWL is not a word line WL to be programmed first in the target word line group (No in step S716), this operation ends.

In step S718, the memory controller 200 determines whether the selected word line SelWL is a word line WL to be programmed first in the block BLK. When the selected word line SelWL is a word line WL to be programmed first in the block BLK (Yes in step S718), this operation ends. On the other hand, when the selected word line SelWL is not a word line WL to be programmed first in the block BLK (No in step S718), this operation proceeds to step S1020.

In step S1020, the memory controller 200 updates the number of unprogrammed cell units NupCU in a previous word line group WLGpre of the target word line group. Specifically, in step S1020, when the target word line group is a word line group WLGn (n is an integer equal to or greater than 1), the memory controller 200 decrements the number of unprogrammed cell units NupCU in the word line group WLG(n−1) by 1. By this step, the program status of the cell units CU connected to the reference word line refWL of the word line group WLG is reflected in the program status related to the word line group WLG stored in the history value table HT. Then, the write process ends.

In the write process, when the selected word line SelWL is a word line WL to be programmed last in the word line group WLG and all of the cell units CU of the target word line group have been programmed (Yes in step S1013), the memory controller 200 updates the program status of the target word line group again, but this is not limiting. That is, for example, instead of incorporating the above steps into the write process, a step of determining whether the block BLK to be sensed has been programmed may be incorporated into the edge word line determination. In this case, for the word line group WLG that is to be programmed last in the block BLK, when the word line group WLG has been programmed, Nsu is stored as the number of unprogrammed cell units NupCU.

### 3.3 Effects

In the memory system of this embodiment, a program status is stored in the history value table HT in units smaller than word lines WL, and it is determined whether to execute history value read in these units. Specifically, in this embodiment, a program status is stored in units of cell units CU, and it is determined whether to execute history value read in units of cell units CU.

Thereby, the memory controller can determine whether to execute history value read by referring to the status of peripheral memory cells in more detail.

In this embodiment, description has been given of an example in which the memory controller 200 stores the program status in units of cell units CU and uses it to determine whether to execute history value read, but this is not limiting. That is, the memory controller 200 may store the program status in units of pages, for example, and use it to determine whether to execute history value read.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory system comprising:
a memory cell array including a plurality of word lines, and a plurality of nonvolatile memory cells that are connected to the plurality of word lines;
a peripheral circuit configured to control the memory cell array;
a memory controller that is electrically connected to the peripheral circuit and configured to group the plurality of word lines into at least one word line group, wherein a first word line group among the at least one word line group includes a first word line among the plurality of word lines; and
a main memory that is included in or electrically connected to the memory controller, the main memory including a first memory area that is a unit of access by the memory controller, wherein
the plurality of nonvolatile memory cells include a first nonvolatile memory cell group connected to the first word line group, and the first word line is connected to a first nonvolatile memory cell in the first nonvolatile memory cell group,
the memory controller is further configured to:
store in the first memory area, first information indicating a program status of the first nonvolatile memory cell group and a first candidate value,
determine, according to the first information, whether to execute a first read operation, and
in response to determining to execute the first read operation, transmit a first read command to execute a sense operation using the first candidate value to the peripheral circuit, and
the peripheral circuit is further configured to, in response to receiving the first read command from the memory controller, perform the sense operation on the first nonvolatile memory cell using the first candidate value.

2. The memory system according to claim 1, wherein
the first word line group further includes a second word line among the plurality of word lines, and the second word line is connected to a second nonvolatile memory cell in the first nonvolatile memory cell group,
the memory controller is further configured to:
determine, according to the first information, whether to execute a second read operation, and
in response to determining to execute the second read operation, transmit a second read command to execute a sense operation using the first candidate value to the peripheral circuit, and
the peripheral circuit is further configured to, in response to receiving the second read command from the memory controller, perform the sense operation on the second nonvolatile memory cell using the first candidate value.

3. The memory system according to claim 2, wherein the memory controller is further configured to:
program data into the first nonvolatile memory cell prior to programming data into the second nonvolatile memory cell, and
determine to execute the first read operation when the first information indicates that the second nonvolatile memory cell has been programmed.

4. The memory system according to claim 3, wherein the memory controller is further configured to determine to execute learning read on the first word line when the first information indicates that the second nonvolatile memory cell has not been programmed.

5. The memory system according to claim 3, wherein
the plurality of word lines further include a third word line that is not included in the first word line group, and the third word line is connected to a third nonvolatile memory cell among the plurality of nonvolatile memory cells, and
the first information further includes a program status of the third nonvolatile memory cell.

6. The memory system according to claim 5, wherein the memory controller is further configured to change the first information in response to a nonvolatile memory cell in the first nonvolatile memory cell group being programmed.

7. The memory system according to claim 6, wherein the memory controller is further configured to change the first information in response to the third nonvolatile memory cell being programmed.

8. The memory system according to claim 7, wherein the memory controller is further configured to:
program data into the second nonvolatile memory cell prior to programming data into the third nonvolatile memory cell, and
determine to execute the second read operation when the first information indicates that the third nonvolatile memory cell has been programmed.

9. The memory system according to claim 8, wherein the memory controller is further configured to determine to execute learning read on the second word line when the first information indicates that the third nonvolatile memory cell has not been programmed.

10. The memory system according to claim 9, wherein
the second word line is adjacent to the first word line, and
the third word line is adjacent to the second word line.

11. The memory system according to claim 8, wherein
the memory cell array includes a first block that is a unit of a data erase operation, and the plurality of nonvolatile memory cells and the plurality of word lines are included in the first block, and
the memory controller is further configured to change the first information to a first initial value in response to the erase operation being performed on the first block.

12. The memory system according to claim 11, wherein
the first word line group includes n word lines, where n is an integer equal to or greater than 2, among the plurality of word lines, and
each of the n word lines is adjacent to at least one of the other n−1 word lines included in the first word line group.

13. The memory system according to claim 12, wherein
the first nonvolatile memory cell group includes n nonvolatile memory cells respectively connected to the n word lines,
the first information is an integer value,
the first initial value is n+1,
the memory controller is further configured to decrement the first information by 1 in response to any of the n nonvolatile memory cells being programmed, decrement the first information by 1 in response to the third nonvolatile memory cell being programmed, and determine to execute the first read operation and determine to execute the second read operation when the first information is 0.

14. The memory system according to claim 12, wherein
the first block includes k string units including the plurality of nonvolatile memory cells, where k is an integer equal to or greater than 2, and
the first nonvolatile memory cell, the second nonvolatile memory cell, and the third nonvolatile memory cell are included in a first string unit among the k string units.

15. The memory system according to claim 14, wherein
the plurality of nonvolatile memory cells include n×k nonvolatile memory cells, of which each set of k nonvolatile memory cells is connected to one of the n word lines, including the third word line,
n nonvolatile memory cells among the n×k nonvolatile memory cells are included in each of the k string units, and each of the k nonvolatile memory cells connected to the third word line is included in the k string units,
the first information is an integer value, and the first initial value is (n+1)×k, and
the memory controller is further configured to
decrement the first information by 1 in response to any of the n×k nonvolatile memory cells being programmed,
decrement the first information by 1 in response to any of the k nonvolatile memory cells connected to the third word line being programmed, and
determine to perform the first read operation and perform the second read operation when the first information is 0.

16. The memory system according to claim 15, wherein the first candidate value is a value indicating a condition under which a sense operation performed on any of the nonvolatile memory cells of the first nonvolatile memory cell group was successful.

17. The memory system according to claim 16, wherein the first candidate value is a shift amount indicating a first voltage applied to one of the word lines of the first word line group connected to one of the nonvolatile memory cells when a sense operation performed on said one of the nonvolatile memory cells was successful.

18. The memory system according to claim 17, wherein the peripheral circuit is further configured to perform a sense operation on the first nonvolatile memory cell by applying the first voltage to the first word line in response to receiving the first read command from the memory controller, and to perform a sense operation on the second nonvolatile memory cell by applying the first voltage to the second word line in response to receiving the second read command from the memory controller.

19. The memory system according to claim 5, wherein
the memory cell array further includes a substrate and a memory pillar extending in a first direction perpendicular to the substrate,
the plurality of word lines are stacked to be spaced apart from each other in the first direction,
the plurality of nonvolatile memory cells are located at intersections of the memory pillar and the plurality of word lines, and
the first word line, the second word line, and the third word line are stacked continuously in the order of the first word line, the second word line, and the third word line or stacked continuously in the order of the third word line, the second word line, and the first word line from a side of the substrate.

20. The memory system according to claim 1, wherein
the memory controller includes a cache memory, the cache memory including a plurality of cache lines, each capable of storing data having a first size, an access speed to the cache memory by the memory controller being higher than an access speed to the main memory by the memory controller,
the first memory area is capable of storing data having the first size, and
the memory controller is further configured to store the data, which is stored in the first memory area, in a first cache line among the plurality of cache lines.
